(19) United States
(12) Patent Application Publication
(10) Pub. No.: US 2023/0213862 A1
(43) Pub. Date: Jul. 6, 2023

(54) PHOTORESIST COMPOSITIONS AND PATTERN FORMATION METHODS

(71) Applicant: ROHM AND HAAS ELECTRONIC MATERIALS LLC, Marborough, MA (US)

(72) Inventors: Li Cui, Westborough, MA (US); Suzanne M. Coley, Mansfield, MA (US); Emad Aqad, Northborough, MA (US); Yinjie Cen, Shrewsbury, MA (US); Jong Keun Park, Shrewsbury, MA (US); Choong-Bong Lee, Westborough, MA (US); James F. Cameron, Brookline, MA (US)

(21) Appl. No.: 18/085,098

(22) Filed: Dec. 20, 2022

Related U.S. Application Data
(60) Provisional application No. 63/294,988, filed on Dec. 30, 2021.

(51) Int. Cl. G03F 7/039

(52) U.S. Cl. CPC G03F 7/0392

(57) ABSTRACT

A photoresist composition, comprising: a first polymer comprising: a first repeating unit comprising a hydroxyaryl group; a second repeating unit comprising a first acid-labile group; and a third repeating unit comprising a first base-soluble group having a pKa of 12 or less, and not comprising a hydroxyaryl group; wherein the first, second, and third repeating units of the first polymer are different from each other, and the first polymer is free of lactone groups; a second polymer comprising: a first repeating unit comprising a second acid-labile group, a second repeating unit comprising a lactone group, and a third repeating unit comprising a second base-soluble group having a pKa of 12 or less; wherein the first, second, and third repeating units of the second polymer are structurally different from each other; and a solvent, wherein the first polymer and the second polymer are different from each other.

### FIELD

The present invention relates to photoresist compositions that contain a blend of two different polymers and to pattern formation methods using such photoresist compositions. The invention finds particular applicability in lithographic applications in the semiconductor manufacturing industry.

### BACKGROUND

Photoresist materials are photosensitive compositions typically used for transferring an image to one or more underlying layers such as a metal, semiconductor or dielectric layer disposed on a semiconductor substrate. To increase the integration density of semiconductor devices and allow for the formation of structures having dimensions in the nanometer range, photoresists and photolithography processing tools having high-resolution capabilities have been and continue to be developed.

Positive-tone chemically amplified photoresists are conventionally used for high-resolution processing. Such resists typically employ a polymer having acid-labile groups and a photoacid generator. Pattern-wise exposure to activating radiation through a photomask causes the acid generator to form an acid which, during post-exposure baking, causes cleavage of the acid-labile groups in exposed regions of the polymer. This creates a difference in solubility characteristics between exposed and unexposed regions of the resist in a developer solution. In a positive tone development (PTD) process, exposed regions of the photoresist layer become soluble in the developer and are removed from the substrate surface, whereas unexposed regions, which are insoluble in the developer, remain after development to form a positive image. The resulting relief image permits selective processing of the substrate.

One approach to achieving nm-scale feature sizes in semiconductor devices is the use of short wavelengths of light, for example, 193 nanometers (nm) or less, during exposure of chemically amplified photoresists. To further improve lithographic performance, immersion lithography tools have been developed to effectively increase the numerical aperture (NA) of the lens of the imaging device, for example, a scanner having a KrF (248 nm) or ArF (193 nm) light source. This is accomplished by use of a relatively high refractive index fluid, typically water, between the last surface of the imaging device and the upper surface of the semiconductor wafer. ArF immersion tools are currently pushing the boundaries of lithography to the 16 nm and 14 nm nodes with the use of multiple (double or higher order) patterning. The use of multiple patterning, however, is generally costly in terms of increased materials usage and number of processing steps required, as compared with single step, directly imaged patterns. This has provided motivation for development of next-generation technologies, such as extreme ultraviolet (EUV) lithography and e-beam lithography. However, as lithographic resolution becomes increasingly higher, line width roughness (LWR) and critical dimension uniformity (CDU) of the photoresist patterns have become of increased importance in forming high-fidelity patterns.

Despite the advancement in resist technology, there is still a need for photoresists compositions that address one or more problems associated with the state of the art. In particular, there is a continuing need for photoresist compositions having good sensitivity, including photoresist compositions that can achieve higher contrast, a lower line width roughness (LWR) for line/space patterns, and/or low critical dimension uniformity (CDU) for contact holes.

### SUMMARY

Provided is a photoresist composition comprising a first polymer including: a first repeating unit including a hydroxyaryl group; a second repeating unit including a first acid-labile group; and a third repeating unit including a first base-soluble group, wherein the first base-soluble group has a pKa of 12 or less, and wherein the first base-soluble group does not comprise a hydroxyaryl group; wherein the first repeating unit, the second repeating unit, and the third repeating unit of the first polymer are structurally different from each other, and wherein the first polymer is free of lactone groups; a second polymer including: a first repeating unit including a second acid-labile group, a second repeating unit including a lactone group, and a third repeating unit including a second base-soluble group having a pKa of 12 or less; wherein the first repeating unit, the second repeating unit, and the third repeating unit of the second polymer are structurally different from each other; and a solvent, wherein the first polymer and the second polymer are different from each other.

Also provided is a method for forming a pattern, the method comprising: (a) forming a photoresist layer from a photoresist composition on a substrate; (b) pattern-wise exposing the photoresist layer to activating radiation; and (c) developing the exposed photoresist layer to provide a resist relief image.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

As used herein, the term “hydrocarbon” refers to an organic compound or group having at least one carbon atom and at least one hydrogen atom; “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl-O—”; “carboxyl” and “carboxylic acid group” refer to a group having the formula “—C(O)—OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl-O—”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic aromatic ring system that satisfies Huckel's Rule (4n+2 π electrons) and includes carbon atoms in the ring; the term “heteroaromatic group” refers to an aromatic group that includes one or more heteroatoms (e.g., 1-4 heteroatoms) selected from N, O, and S instead of a carbon atom in the ring; “aryl” refers to a monovalent monocyclic or polycyclic aromatic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl-O—”; and “arylthio” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl” refers to an alkyl group having at least one heteroatom instead of carbon; “heterocycloalkyl” refers to a cycloalkyl group having 1-4 heteroatoms as ring members instead of carbon; “heterocycloalkylene” refers to a heterocycloalkyl group having a valence of two; “heteroaryl” refers to an aromatic 4-8 membered monocyclic, 8-12 membered bicyclic, or 11-14 membered tricyclic ring system having 1-4 heteroatoms (if monocyclic), 1-6 heteroatoms (if bicyclic), or 1-9 heteroatoms (if tricyclic) that are each independently selected from N, O, S, Si, or P (e.g., carbon atoms and 1-3, 1-6, or 1-9 heteroatoms of N, O, or S, if monocyclic, bicyclic, or tricyclic, respectively). Examples of heteroaryl groups include pyridyl, furyl (furyl or furanyl), imidazolyl, benzimidazolyl, pyrimidinyl, thiophenyl or thienyl, quinolinyl, indolyl, thiazolyl, and the like; and “heteroarylene” refers to a heteroaryl group having a valence of two.

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present. For example, the term “haloalkyl” refers to an alkyl group substituted with one or more halogens. As used herein, “substituted C₁₋₈ haloalkyl” refers to a C₁₋₈ alkyl group substituted with at least one halogen, and is further substituted with one or more other substituent groups that are not halogens. It is to be understood that substitution of a group with a halogen atom is not to be considered a heteroatom-containing group, because a halogen atom does not replace a carbon atom.

The term “fluorinated” means having one or more fluorine atoms incorporated into a group instead of hydrogen. For example, where a C₁₋₁₈ fluoroalkyl group is indicated, the fluoroalkyl group can include one or more fluorine atoms, for example, a single fluorine atom, two fluorine atoms (e.g., as a 1,1-difluoroethyl group), three fluorine atoms (e.g., as a 2,2,2-trifluoroethyl group), or fluorine atoms at each valence of carbon (e.g., as a perfluorinated group such as —CF₃, —C₂F₅, —C₃F₇, or —C₄F₉). A “substituted fluoroalkyl group” shall be understood to mean a fluoroalkyl group that is further substituted by at least one additional substituent group that does not contain fluorine atoms.

As used herein, a “hydroxyaryl group” and a “hydroxy-substituted aryl group” refer to an aryl group in which hydroxy is bonded directly to an aromatic ring carbon. “Hydroxy” shall be understood to mean having one or more hydroxy groups incorporated into the group. For example, where a C₆₋₁₂ hydroxy-aryl group is indicated, the hydroxy-aryl group can include one or more hydroxy groups, for example, a single hydroxy group, two hydroxy groups, three or more hydroxy groups, and the like. A “substituted hydroxy-aryl group” shall be understood to mean a hydroxy-aryl group that is further substituted by an additional substituent group.

Each of the foregoing substituent groups optionally may be substituted unless expressly provided otherwise. The term “optionally substituted” refers to being substituted or unsubstituted. “Substituted” means that at least one hydrogen atom of the chemical structure or group is replaced with another terminal substituent group that is typically monovalent, provided that the designated atom's normal valence is not exceeded. When the substituent is oxo (i.e., O), then two geminal hydrogen atoms on the carbon atom are replaced with the terminal oxo group. It is further noted that the oxo group is bonded to carbon via a double bond to form a carbonyl (C═O), where the carbonyl group is represented herein as —C(O)—. Combinations of substituents or variables are permissible. Exemplary substituent groups that may be present on a “substituted” position include, but are not limited to, nitro (—NO₂), cyano (—CN), hydroxyl (—OH), oxo (O), amino (—NH₂), mono- or di-(C₁₋₆)alkylamino, alkanoyl (such as a C₂₋₆ alkanoyl group such as acyl), formyl (—C(O)H), carboxylic acid or an alkali metal or ammonium salt thereof; esters (including acrylates, methacrylates, and lactones) such as C₂₋₆ alkyl esters (—C(O)O-alkyl or —OC(O)-alkyl) and C₇₋₁₃ aryl esters (—C(O)O-aryl or —OC(O)-aryl); amido (—C(O)NR₂ wherein R is hydrogen or C₁₋₆ alkyl), carboxamido (—CH₂C(O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(O)₂-alkyl), C₆₋₁₂ arylsulfonyl (—S(O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a cyano-substituted C₂ alkyl group.

As used herein, when a definition is not otherwise provided, a “divalent linking group” refers to a divalent group including one or more of —O—, —S—, —Te—, —Se—, —C(O)—, C(O)O—, —N(R′)—, —C(O)N(R′)—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein each R′ is independently hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —N(R′)—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. More typically, the divalent linking group includes at least one of —O—, —C(O)—, —C(O)O—, —N(R′)—, —C(O)N(R′)—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R is hydrogen, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

As used herein, an “acid-labile group” refers to a group in which a bond is cleaved by the action of an acid, optionally and typically with thermal treatment, resulting in formation of a polar group, such as a carboxylic acid or alcohol group, being formed on the polymer, and optionally and typically with a moiety connected to the cleaved bond becoming disconnected from the polymer. In other systems, a non-polymeric compound may include an acid-labile group that may be cleaved by the action of an acid, resulting in formation of a polar group, such as a carboxylic acid or alcohol group on a cleaved portion of the non-polymeric compound. Such acid is typically a photo-generated acid with bond cleavage occurring during post-exposure baking (PEB); however, embodiments are not limited thereto, and, for example, such acid may be thermally generated. Suitable acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

The term “unsaturated bond” refers to a double or triple bond. The term “unsaturated” or “partially unsaturated” refers to a moiety that includes at least one double or triple bond. The term “saturated” refers to a moiety that does not contain a double or triple bond, i.e., the moiety only contains single bonds.

As used herein, the term “(meth)acrylic” includes both acrylic and methacrylic species (i.e., acrylic and methacrylic monomers), and the term “(meth)acrylate” includes both acrylate and methacrylate species (i.e., acrylate and methacrylate monomers).

The present invention relates to photoresist compositions that include a blend of a first polymer, a second polymer, and a solvent, and may contain additional, optional components. The first polymer and the second polymer are different from each other. For example, the photoresist composition may further include a photoacid generator (PAG). Suitable PAGs can generate an acid that, during post-exposure bake (PEB), causes cleavage of acid-labile groups present on a polymer of the photoresist composition. The inventors have discovered that particular photoresist compositions of the invention can be used to prepare photoresist films that have improved lithographic properties, for example, improved contrast, LWR, CDU, and/or excellent sensitivity.

The first polymer of the photoresist composition includes at least three different repeating units. The first polymer includes a first repeating unit that comprises a hydroxyaryl group, a second repeating unit that comprises a first acid-labile group, and a third repeating unit that comprises a first base-soluble group. It is to be understood that the first repeating unit, the second repeating unit, and the third repeating unit of the first polymer are structurally different from each other. The first polymer is free of lactone groups (i.e., the first polymer does not comprise a lactone).

The first base-soluble group has a pKa of 12 or less. In addition, the first base-soluble group does not comprise a hydroxyaryl group (e.g., is not a hydroxyaryl group). Preferably, the first base-soluble group has a pKa from 2 to 12, more preferably from 3 to 9, and most preferably from 4 to 8. The pKa is typically measured in an aqueous solution at 25° C. and may be determined experimentally, for example, by potentiometric titration such as by using a potentiometric pH meter available from Sirius Analytical Instruments Ltd., or may be calculated, for example, by using Advanced Chemistry Development (ACD) Labs Software Version 11.02. When an acid value of a functional group having a relatively high pKa (e.g., a —C(CF₃)₂OH group) is to be measured, a non-aqueous titrant such as an organic solvent or organic solvent mixture may be used.

The first repeating unit of the first polymer includes a hydroxyaryl group. The first repeating unit of the first polymer may be derived from a monomer of formula (1):

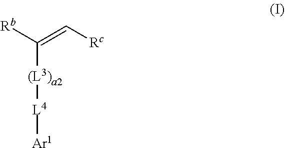

In formula (1), R^{b} is hydrogen, halogen, or substituted or unsubstituted C₁₋₁₀ alkyl. Preferably, R^{b} is hydrogen, or substituted or unsubstituted C₁₋₅ alkyl, typically methyl.

In formula (1), R^{c} is hydrogen, —C(O)— forming a ring with L⁴, or a single bond forming a ring with Ar¹. Preferably, R^{c} is hydrogen.

In formula (1), L³ is —O—, —C(O)—, or —C(O)—O—, wherein a2 is 0 or 1. It is to be understood that when a2 is 0, group L³ is not present, and therefore L⁴ is directly bonded to the alkenyl (vinylic) carbon atom.

In formula (1), L⁴ is a single bond, or one or more divalent linking groups. For example, L⁴ may be a divalent linking group including one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₁₋₃₀ heteroarylene, —O—, —C(O)—, —C(O)O—, —C(O)NR^{1a}—, or —N(R^{1b})—, wherein R^{1a} and R^{1b} are each independently hydrogen, C₁₋₆ alkyl, or a single bond forming the ring with W.

It is to be understood that when a2 is 0 and L⁴ is a single bond, then Ar¹ is directly bonded to the alkenyl (vinylic) carbon atom.

In formula (1), Ar¹ is a hydroxy-substituted C₆₋₆₀ aryl group, a hydroxy-substituted C₅₋₆₀ heteroaryl group, or a combination thereof. Each of the hydroxy-substituted C₆₋₆₀ aryl group and the hydroxy-substituted C₅₋₆₀ heteroaryl group optionally may be further substituted with one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, or substituted or unsubstituted C₄₋₃₀ heteroarylalkyl, —OR^{1c}, or —NR^{1d}R^{1e}, wherein R^{1c} to R^{1e} are each independently substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₃₋₃₀ heteroaryl, or substituted or unsubstituted C₄₋₃₀ heteroarylalkyl. It may be desired for Ar¹ to comprise a single hydroxyl group or a plurality of hydroxyl groups (e.g., Ar¹ may be a hydroxy-substituted C₆₋₆₀ aryl group, a hydroxy-substituted C₅₋₆₀ heteroaryl group, or a combination thereof, each of which is independently optionally further substituted with a hydroxy group).

Non-limiting examples of monomers of formula (1) include:

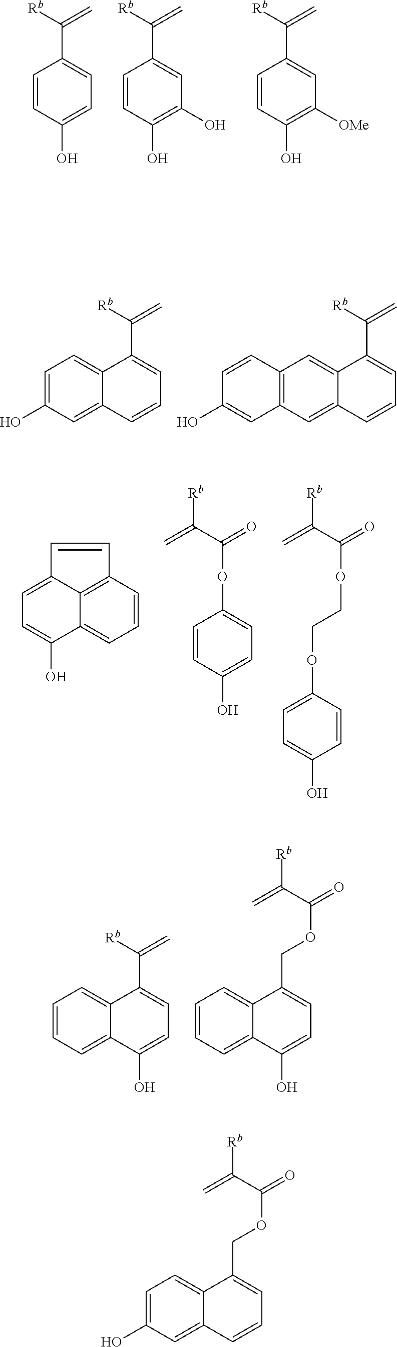

wherein R^{b} is as defined for formula (1).

The first repeating unit is typically present in the first polymer in an amount from 10 to 70 mole percent (mol %), typically from 15 to 60 mol %, and more typically from 20 to 50 mol %, based on total repeating units in the first polymer.

The second repeating unit of the first polymer includes a first acid-labile group, and may be derived from a monomer represented by one or more of Formulae (2a), (2b), (2c), (2d), or (2e):

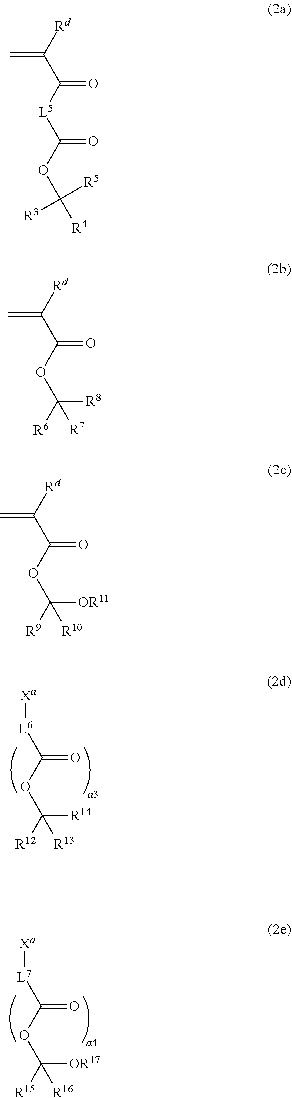

In formulae (2a), (2b), and (2c), each R^{d} is independently hydrogen, halogen, or substituted or unsubstituted C₁₋₁₀ alkyl. Preferably, each R^{d} is independently be hydrogen, or substituted or unsubstituted C₁₋₅ alkyl, typically methyl.

In formula (2a), L⁵ is one or more divalent linking groups. For example, L⁵ may include 1 to 10 carbon atoms and at least one heteroatom. In a typical example, L⁵ may be —OCH₂—, —OCH₂CH₂O—, or —N(R^{2a})—, wherein R^{2a} is hydrogen or C₁₋₆ alkyl.

In formula (2a), (2b), (2c), (2d), and (2e), R³ to R⁵, R⁶ to R⁸, R⁹, R¹⁰, R¹² to R¹⁴, R¹⁵, and R¹⁶ are each independently hydrogen, substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₃₋₂₀ heteroaryl, provided that no more than one of R³ to R⁵ may be hydrogen, no more of one of R⁶ to R⁸ may be hydrogen, and no more of one of R¹² to R¹⁴ may be hydrogen. If one of R³ to R⁵ is hydrogen, then at least one of the others from R³ to R⁵ is substituted or unsubstituted C₆₋₂₀ aryl or substituted or unsubstituted C₃₋₂₀ heteroaryl; if one of R⁶ to R⁸ is hydrogen, then at least one of the others from R⁶ to R⁸ is substituted or unsubstituted C₆₋₂₀ aryl or substituted or unsubstituted C₃₋₂₀ heteroaryl; and if one of R¹² to R¹⁴ is hydrogen, then at least one of the others from R¹² to R¹⁴ is substituted or unsubstituted C₆₋₂₀ aryl or substituted or unsubstituted C₃₋₂₀ heteroaryl. Preferably, R³ to R⁵, R⁶ to R⁸, R⁹, R¹⁰, R¹² to R¹⁴, R¹⁵ and R¹⁶ are each independently substituted or unsubstituted C₁₋₆ alkyl or substituted or unsubstituted C₃₋₁₀ cycloalkyl.

Each of R³ to R⁵, R⁶ to R⁸, R⁹, R¹⁰, R¹² to R¹⁴, R¹⁵, and R¹⁶ may optionally further comprise one or more divalent linking group as part of their structure, wherein each of the one or more divalent linking groups is substituted or unsubstituted. For example, any one or more of R³ to R⁵, R⁶ to R⁸, R⁹, R¹⁰, R¹² to R¹⁴, R¹⁵, and R¹⁶ may be independently a group of formula —CH₂C(O)CH₍₃₋ₙ₎Yₙ, or —CH₂C(O)OCH₍₃₋ₙ₎ Yₙ, where each Y is independently substituted or unsubstituted C₃₋₁₀ heterocycloalkyl and n is 1 or 2. For example, each Y may be independently substituted or unsubstituted C₃₋₁₀ heterocycloalkyl including a group of the formula —O(C^{a1})(C^{a2})O—, wherein C^{a1} and C^{a2} are each independently hydrogen or substituted or unsubstituted alkyl, and where C^{a1} and C^{a2} together optionally form a ring.

In formulae (2c) and (2e), R¹¹ and R¹⁷ are each independently substituted or unsubstituted C₁₋₂₀ alkyl, substituted or unsubstituted C₃₋₂₀ cycloalkyl, or substituted or unsubstituted C₃₋₂₀ heterocycloalkyl.

In formulae (2d) and (2e), X^{a} and X^{b} are each independently a polymerizable group comprising an ethylenically unsaturated double bond, preferably (meth)acrylate or C₂ alkenyl.

In formulae (2d) and (2e), a3 and a4 are each independently 0 or 1.

In formulae (2d) and (2e), L⁶ and L⁷ are each independently a single bond, or one or more divalent linking group, provided that L⁶ is not a single bond when X^{a} is C₂ alkenyl and that L⁷ is not a single bond when X^{b} is C₂ alkenyl. Preferably, L⁶ and L⁷ are each independently substituted or unsubstituted C₆₋₃₀ arylene or substituted or unsubstituted C₆₋₃₀ cycloalkylene.

In formula (2a), any two of R³ to R⁵ together optionally form a ring that optionally further comprises one or more divalent linking groups as part of its structure, wherein each of the one or more divalent linking groups is substituted or unsubstituted, and wherein the ring is substituted or unsubstituted.

In formula (2b), any two of R⁶ to R⁸ together optionally form a ring that optionally further comprises one or more divalent linking groups as part of its structure, wherein each of the one or more divalent linking groups is substituted or unsubstituted, and wherein the ring is substituted or unsubstituted.

In formula (2c), any two of R⁹ to R¹¹ together optionally form a ring that optionally further comprises one or more divalent linking groups as part of its structure, wherein each of the one or more divalent linking groups is substituted or unsubstituted, and wherein the ring is substituted or unsubstituted.

In formula (2d), any two of R¹² to R¹⁴ together optionally form a ring that optionally further comprises one or more divalent linking groups as part of its structure, wherein each of the one or more divalent linking groups is substituted or unsubstituted, and wherein the ring is substituted or unsubstituted.

In formula (2e), any two of R¹⁵ to R¹⁷ together optionally form a ring that optionally further comprises one or more divalent linking group as part of its structure, wherein each of the one or more divalent linking groups is substituted or unsubstituted, and wherein the ring is substituted or unsubstituted.

In some aspects, in a repeating unit comprising an acid-labile group, the acid-labile group may be a tertiary alkyl ester. For example, a repeating unit comprising a tertiary alkyl ester group may be derived from one or more monomers of Formulae (2a), (2b), or (2d), wherein none of R³ to R⁸ or R¹² to R¹⁴ is hydrogen, and a3 is 1. In one or more embodiments, the first acid-labile group and the second acid-labile group are each independently chosen from tertiary ester groups. In other words, in some embodiments, each of the first acid-labile group and the second acid-labile group may be a tertiary alkyl ester group, wherein the tertiary alkyl ester groups are the same or different.

Exemplary monomers of formula (2a) include one or more of the following:

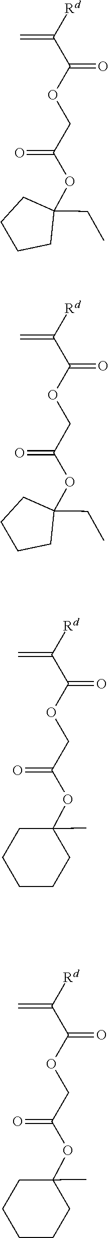

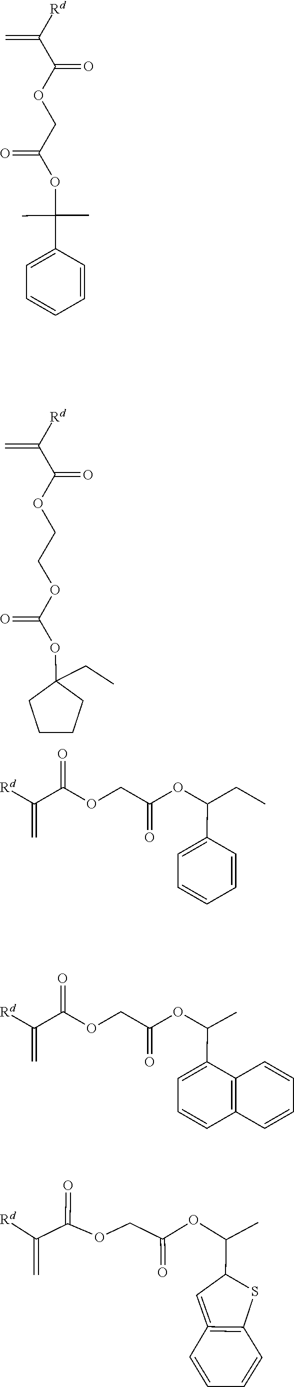

wherein R^{d} is as defined for formula (2a).

Exemplary monomers of formula (2b) include one or more of the following:

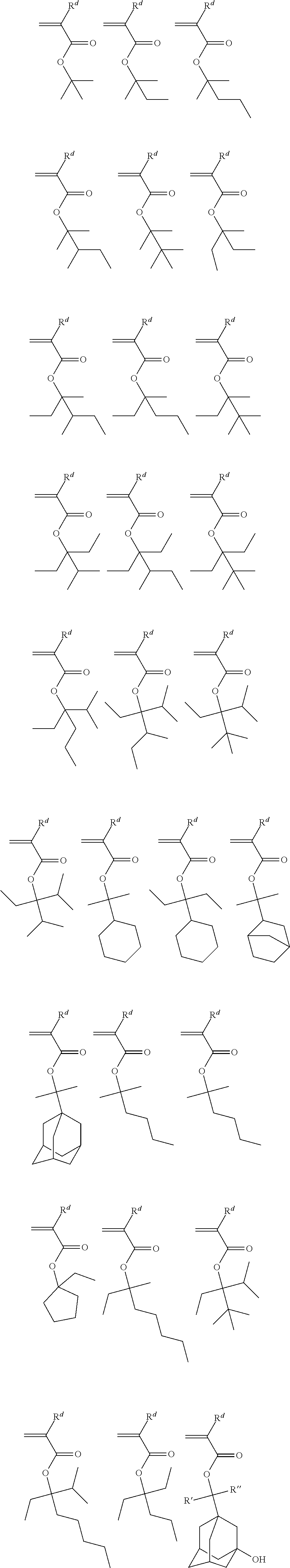

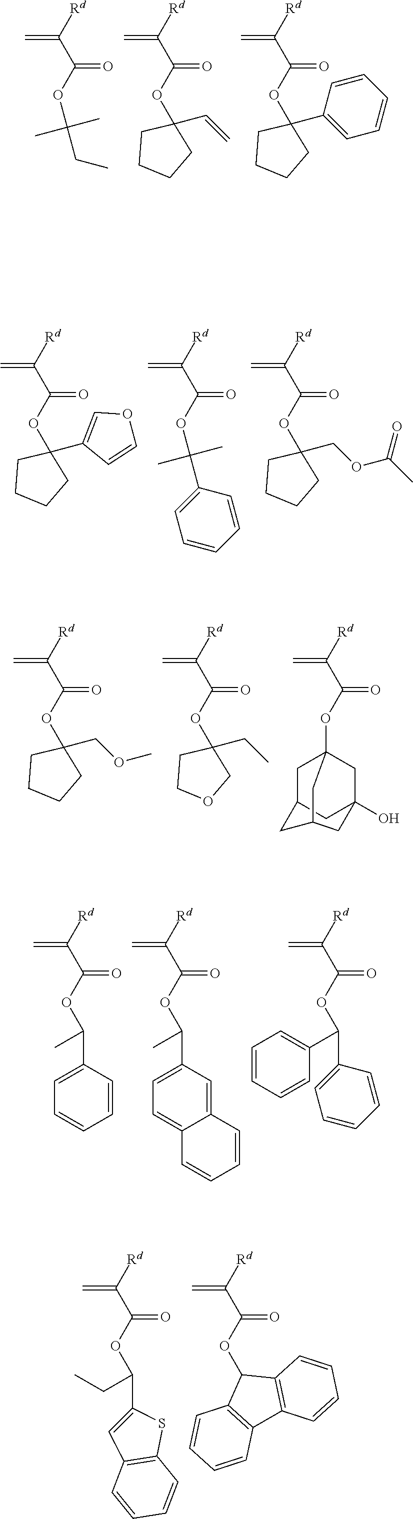

wherein R^{d} is as defined for formula (2b), and R′ and R″ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₃₋₂₀ heteroaryl.

Exemplary monomers of formula (2c) include one or more of the following:

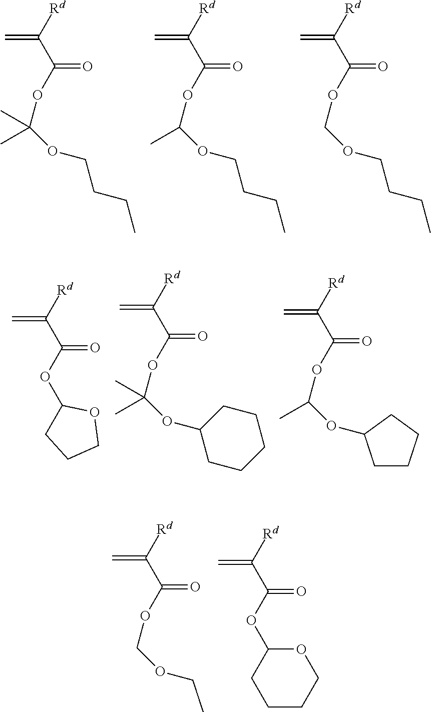

wherein R^{d} is as defined for formula (2c).

Exemplary monomers of formula (2d) include one or more of the following:

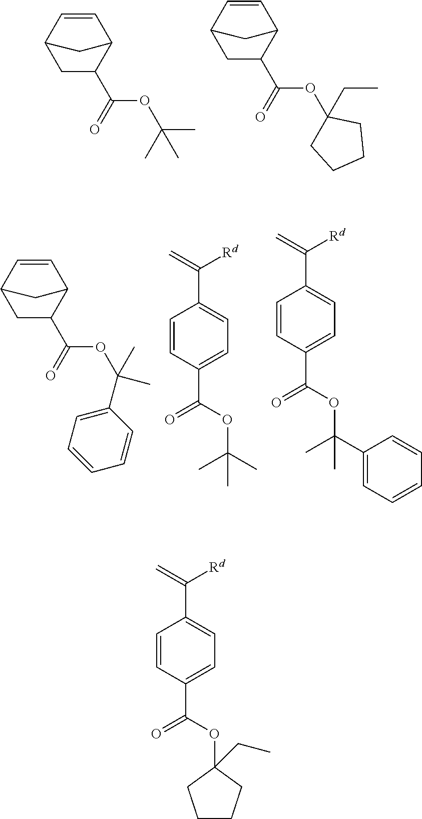

wherein R^{d} is as defined for formula (2d).

Exemplary monomers of formula (2e) include one or more of the following:

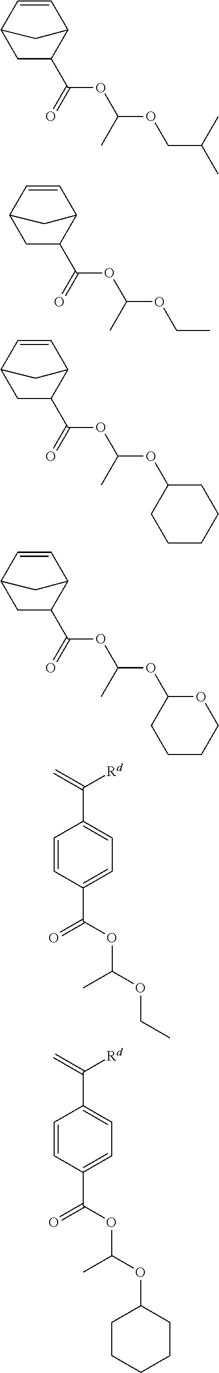

wherein R^{d} is as defined for formula (2e).

In some aspects, the first acid-labile repeating unit may be derived from one or more monomers having a cyclic acetal or cyclic ketal group, for example, having one or more of the following structures:

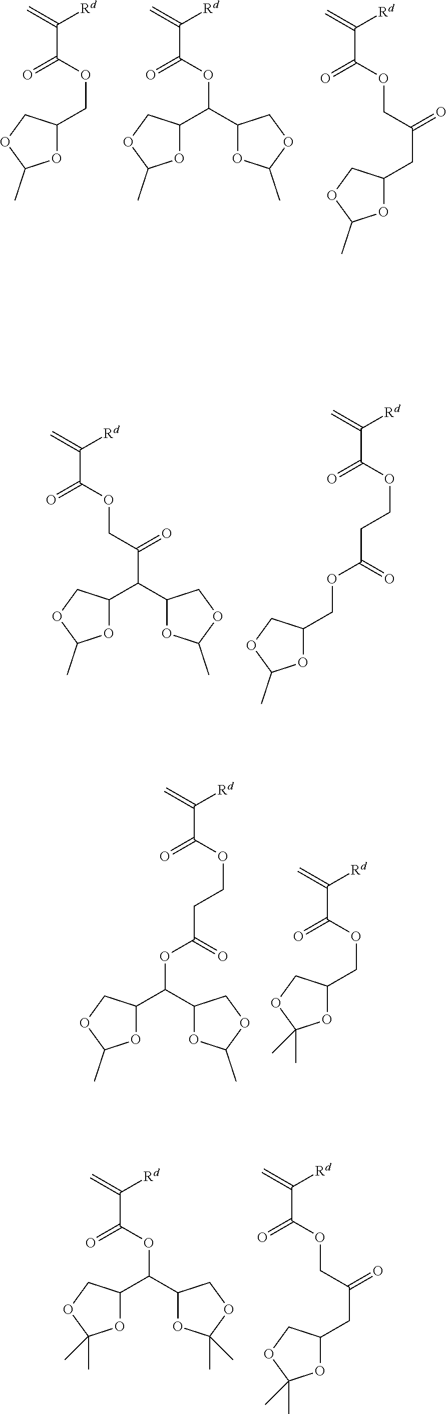

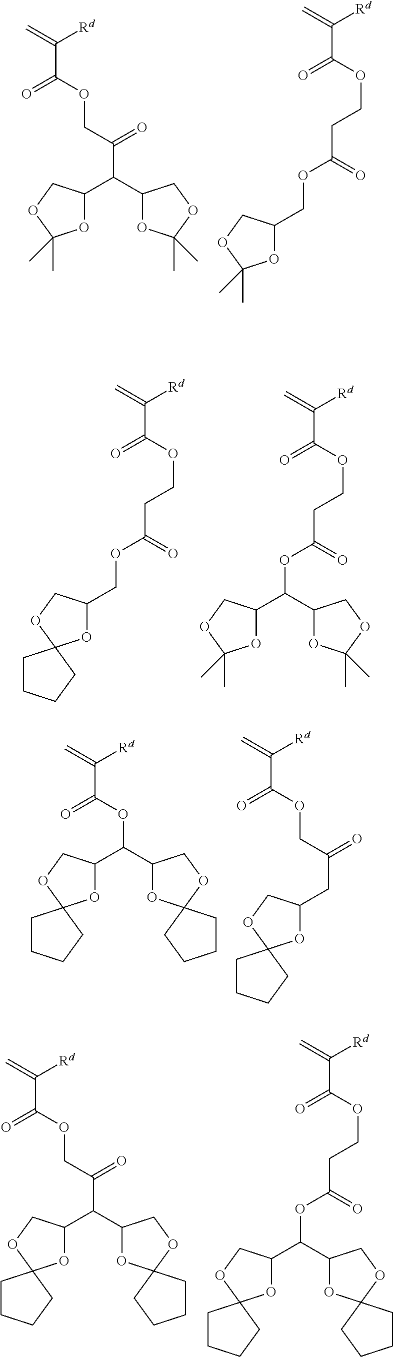

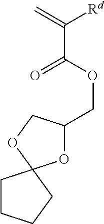

wherein R^{d} is as defined for formula (2a).

In some aspects, the second repeating unit of the first polymer may be a repeating unit having an acid-labile group that includes a tertiary alkoxy group, for example, one or more monomers of the following:

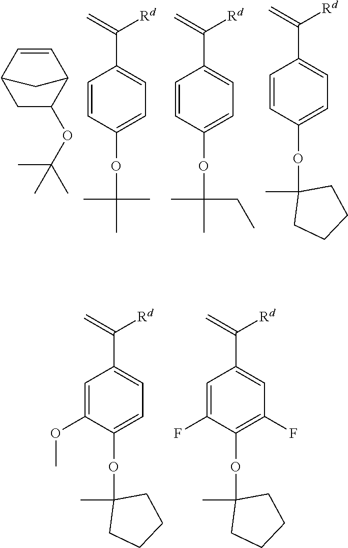

wherein R^{d} is as defined for formula (2a).

The second repeating unit of the first polymer is typically present in an amount from 30 to 75 mol %, more typically from 30 to 70 mol %, still more typically from 35 to 60 mol %, based on total repeating units in the first polymer.

The third repeating unit of the first polymer includes a first base-soluble group, wherein the first base-soluble group has a pKa of 12 or less, and wherein the first base-soluble group does not comprise a hydroxyaryl group. For example, the first base-soluble group may comprise a fluoroalcohol group (e.g., —C(CF₃)₂OH), a carboxylic acid group (e.g., —C(O)OH), a carboximide group (e.g., —(O)C—NH—C(O)—Y¹ where Y¹ is a divalent linking group or a terminal substituent group), a sulfonamide group (e.g., —S(O)₂NH—Y², where Y² is a divalent linking group or a terminal substituent group), or a sulfonimide group (e.g., —S(O)₂—NH—S(O)₂—Y³ where Y³ is a divalent linking group or a terminal substituent group).

In some embodiments, the third repeating unit of the first polymer may be derived from a monomer comprising fluoroalcohol group of formula (3):

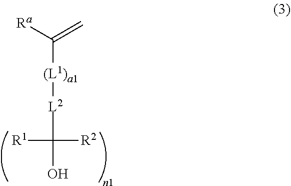

In formula (3), R^{a} may be hydrogen, halogen, or substituted or unsubstituted C₁₋₁₀ alkyl. Preferably, R^{a} may be hydrogen, or substituted or unsubstituted C₁₋₅ alkyl, typically methyl.

In formula (3), L¹ may be —O—, —C(O)—, —C(O)O—, or —C(O)NR′— wherein R′ is hydrogen or a substituted or unsubstituted C₁₋₅ alkyl group, and wherein a1 is 0 or 1. It is to be understood that when a1 is 0, L¹ is considered a single bond (or absent) and group L² is directly bonded to the alkenyl (vinylic) carbon atom.

In formula (3), L² is a single bond or a multivalent linking group chosen, for example, from one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₇₋₃₀ arylalkylene, substituted or unsubstituted C₁₋₃₀ heteroarylene, substituted or unsubstituted divalent C₃₋₃₀ heteroarylalkylene, —O—, —C(O)—, or —C(O)O—.

In formula (3), n1 is an integer from 1 to 5, and typically n1 is 1 or 2. It is to be understood that when n1 is 1, the group L² is one or more divalent linking groups. It is to be understood that when n1 is 2, the group L² is a trivalent linking group. Similarly, it is to be understood that when n1 is 3, the group L² is a tetravalent linking group; when n1 is 4, the group L² is a pentavalent linking group; and when n1 is 5, the group L² is a hexavalent linking group.

In formula (3), each R¹ is a substituted or unsubstituted C₁₋₁₂ perfluoroalkyl group. It is to be understood that a “substituted C₁₋₁₂ perfluoroalkyl” refers to a perfluoroalkyl group wherein at least one fluorine atom is replaced with another terminal substituent group that is not fluorine. Preferably, R¹ may be —CF₃, —C₂F₅, —C₃F₇, or —C₄F₉.

In formula (3), each R² is substituted or unsubstituted C₁₋₁₂ alkyl, substituted or unsubstituted C₃₋₁₂ cycloalkyl, or substituted or unsubstituted C₁₋₁₂ heterocycloalkyl, wherein R² optionally comprises one or more fluorine atoms. Typically, R² may be —CF₃, —C₂F₅, —C₃F₇, or —C₄F₉. In some aspects, R¹ and R² are the same. In other aspects, R² is a substituted or unsubstituted C₁₋₁₂ perfluoroalkyl group that is different from W.

Exemplary monomers of formula (3) may include one or more of the following:

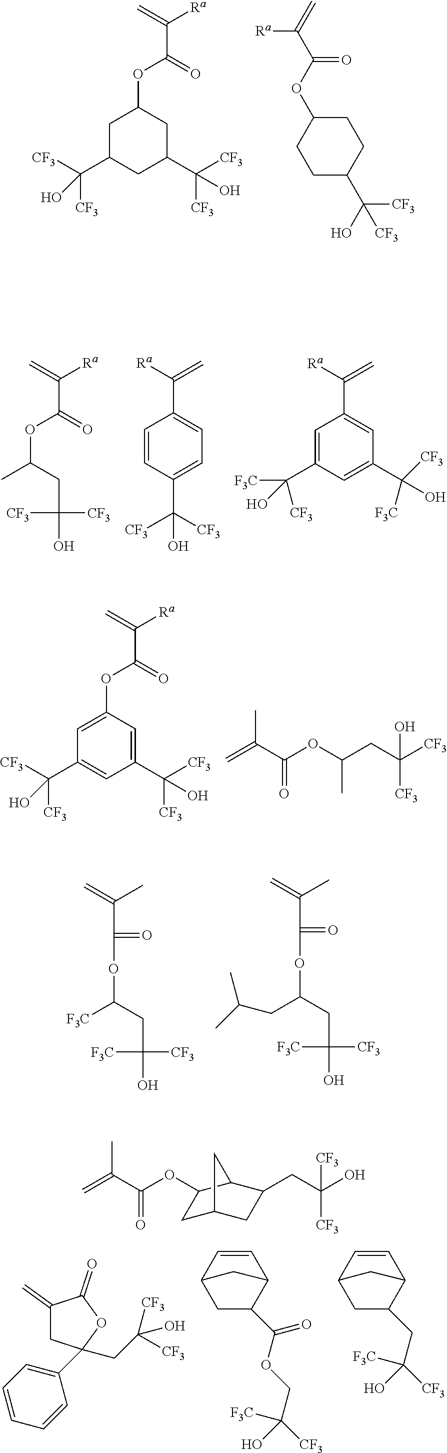

wherein W is as defined for formula (3).

The third repeating unit of the first polymer is typically present in an amount from 1 to 25 mol %, more typically from 5 to 20 mol %, still more typically from 5 to 15 mol %, based on total repeating units in the first polymer.

Non-limiting exemplary first polymers of the present invention include one or more of the following:

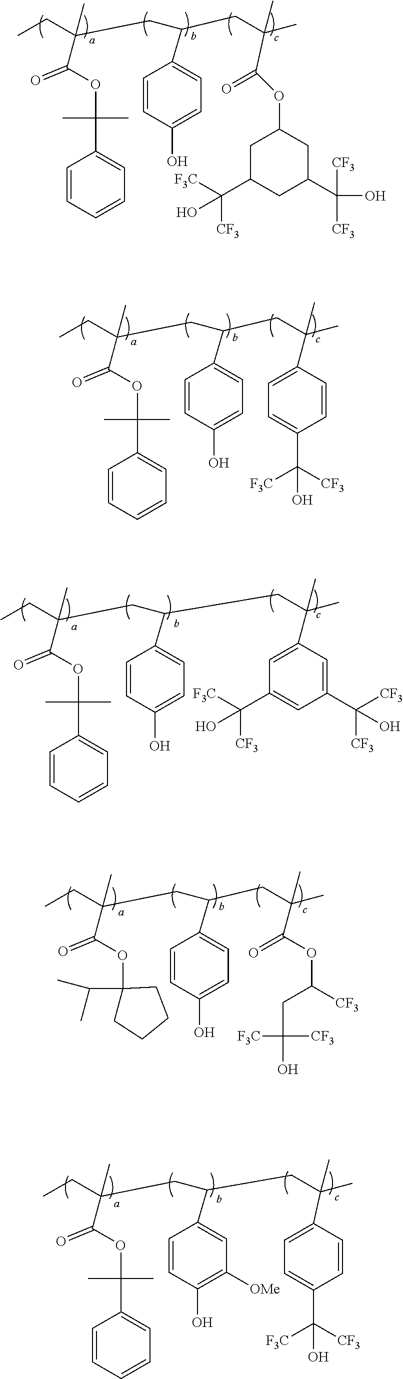

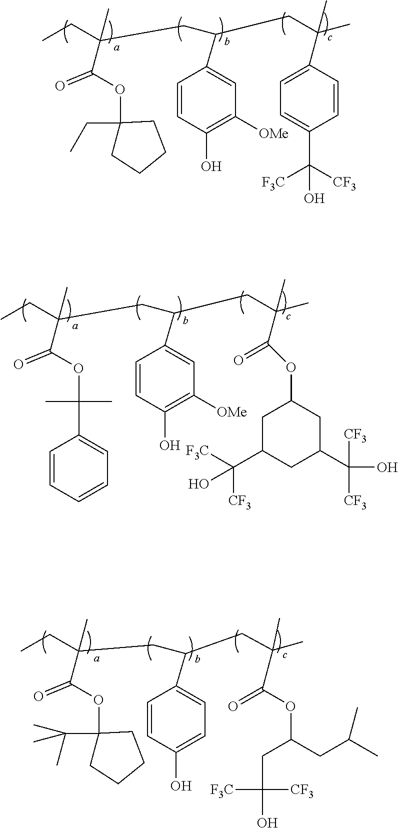

wherein a, b, and c each indicate the relative molar amounts of the respective repeating unit(s).

The first polymer typically has a weight average molecular weight (M_{w}) from 1,000 to 50,000 Dalton (Da), preferably from 2,000 to 30,000 Da, more preferably 3,000 to 20,000 Da, and still more preferably from 4,000 to 15,000 Da. The polydispersity index (PDI) of the first polymer, which is the ratio of M_{w}, to number average molecular weight (Mₙ) is typically from 1.1 to 3, and more typically from 1.1 to 2. Molecular weight values are determined by gel permeation chromatography (GPC) using polystyrene standards.

The second polymer of the photoresist composition includes at least three different repeating units. The second polymer includes a first repeating unit that comprises a second acid-labile group, a second repeating unit that comprises a lactone group, and a third repeating unit that comprises a second base-soluble group, wherein the second based-soluble group has a pKa of 12 or less.

The first repeating unit of the second polymer includes an acid-labile group, which is referred to herein as the “second acid-labile group” to differentiate from the acid-labile group of the first polymer. It is to be understood that there is no “first” acid-labile group in the second polymer. The second acid-labile group may be derived from a monomer represented by one or more of Formulae (2a), (2b), (2c), (2d), or (2e), or may be derived from one or more monomers having a cyclic acetal or cyclic ketal group, or one or more monomers having tertiary alkoxy groups, as described for the first acid-labile group in the first polymer. In some aspects, the first acid-labile group and the second acid-labile group may be the same acid-labile groups. In other aspects, the first acid-labile group and the second acid-labile group may be different acid-labile groups.

In one or more embodiments, the second acid-labile group may be a tertiary alkyl ester. For example, the first repeating unit of the second polymer may include a repeating unit comprising a tertiary alkyl ester group that is derived from one or more monomers of Formulae (2a), (2b), or (2d), wherein none of R³ to R⁸ or R¹² to R¹⁴ is hydrogen, and a3 is 1. In one or more embodiments, the first acid-labile group and the second acid-labile group are each independently chosen from tertiary ester groups. In other words, in some embodiments, each of the first acid-labile group and the second acid-labile group may be a tertiary alkyl ester group, wherein the tertiary alkyl ester groups are the same or different.

The first repeating unit of the second polymer is typically present in an amount from 30 to 65 mol %, more typically from 30 to 60 mol %, still more typically from 35 to 55 mol %, based on total repeating units in the second polymer.

The second repeating unit of the second polymer includes a lactone group. It is to be understood that the lactone group of the second polymer may be pendant to the backbone of the second polymer, or a carbon atom of a lactone ring in a second repeating unit may form a part of the backbone of the second polymer (i.e., wherein the lactone ring of the second repeating unit shares a tertiary carbon atom with the backbone of the second polymer, and thus the lactone ring is incorporated directly into the backbone of the second polymer).

In some embodiments, the second repeating unit of the second polymer may be derived from one or more monomers of Formulae (4a) or (4b):

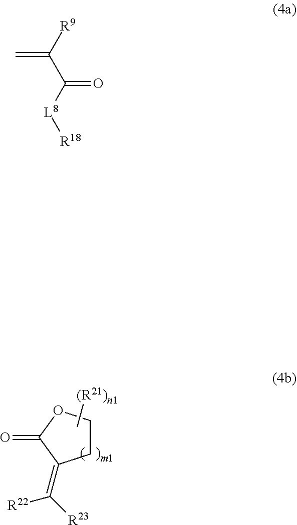

In formula (4a), R^{g} is hydrogen, halogen, or substituted or unsubstituted C₁₋₁₀ alkyl. Preferably, R^{g} may be hydrogen, or substituted or unsubstituted C₁₋₅ alkyl, typically methyl.

In formula (4a), L⁸ is a single bond or one or more divalent linking group. Exemplary divalent linking groups for L⁸ include one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, —O—, —C(O)—, —C(O)O—, —S—, —S(O)₂—, —N(R^{9a})—, or —C(O)N(R^{9b})—, wherein R^{9a} and R^{9b} may be each independently hydrogen, substituted or unsubstituted C₁₋₂₀ alkyl, substituted or unsubstituted C₃₋₂₀ cycloalkyl, or substituted or unsubstituted C₃₋₂₀ heterocycloalkyl.

It is to be understood that when L⁸ is a single bond, the moiety —R¹⁸ is directly connected to the oxygen atom adjacent to the carbonyl group (i.e., —C(O)OR¹⁸).

In formula (4a), R¹⁸ is a substituted or unsubstituted C₄₋₂₀ lactone-containing group. The C₄₋₂₀ lactone-containing group may be monocyclic, polycyclic, or fused polycyclic.

In formula (4b), each R²¹ is independently halogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl, wherein each R²¹ optionally further comprises a divalent linking group as part of its structure. Preferably, each R²¹ is independently halogen, substituted or unsubstituted C₁₋₈ alkyl, substituted or unsubstituted C₃₋₁₅ cycloalkyl, or substituted or unsubstituted C₃₋₁₅ heterocycloalkyl, typically substituted or unsubstituted C₁₋₃ alkyl.

In formula (4b), R²² and R²³ are each independently hydrogen, halogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₃₋₂₀ heterocycloalkyl, C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl, wherein each of R²² and R²³ independently optionally further includes a divalent linking group as part of their structure. Preferably, R²² and R²³ are each independently hydrogen, halogen, substituted or unsubstituted C₁₋₈ alkyl, substituted or unsubstituted C₃₋₁₅ cycloalkyl, or substituted or unsubstituted C₃₋₁₅ heterocycloalkyl, typically hydrogen.

In formula (4b), any two or more of R²¹, R²², and R²³ optionally together may form a ring via a single bond or a divalent linking group.

In formula (4b), m1 is 1 or 2, and n1 is an integer from 1 to 6. It is to be understood that when m1 is 1, n1 is an integer from 1 to 4, and when m1 is 2, n1 is an integer from 1 to 6. Preferably, n1 is an integer from 1 to 4, typically 1 or 2.

Non-limiting examples of monomers of formula (4b) include those of Formulae (4c), (4d), and (4e):

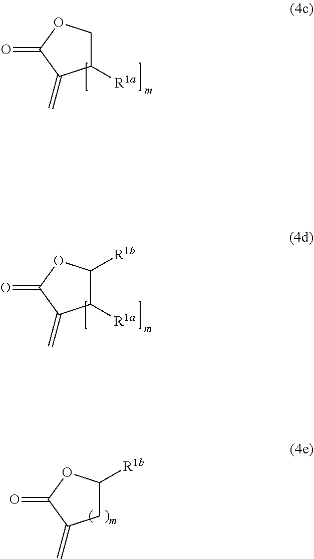

wherein m is 1 or 2; each R^{1a} may independently be hydrogen or unsubstituted C₁₋₂ alkyl, provided that at least one R^{1a} is unsubstituted C₁₋₂ alkyl, typically, at least one R^{1a} is methyl (e.g., when m is 2, a first R^{1a} group adjacent to the carbon-carbon double bond may be a methyl group and a second R^{1a} group may be hydrogen; and R^{1b} is unsubstituted C₁₋₂ alkyl, typically methyl); R^{1b} is unsubstituted C₁₋₂ alkyl, typically methyl.

Exemplary monomers of formula (4a) may include one or more of the following:

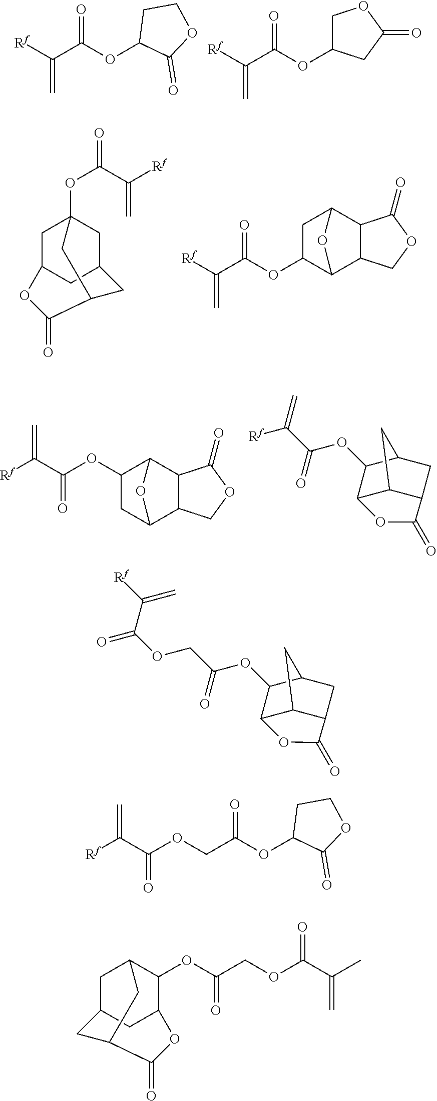

wherein R^{f} is as defined for R^{g} formula (4a).

The second polymer typically comprises the second repeating unit in an amount from 15 to 65 mol %, typically from 15 to 60 mol %, and more typically from 15 to 55 mol %, based on total moles of repeating units in the second polymer.

The third repeating unit of the second polymer includes a base-soluble group having a pKa of 12 or less, which is referred to herein as the “second base-soluble group” to differentiate from the first base-soluble group of the first polymer. It is to be understood that there is no “first” base-soluble group in the second polymer. The second base-soluble group of the second polymer may, in some embodiments, comprise a hydroxyaryl group, unlike the first base-soluble group of the first polymer. In some embodiments, the second base-soluble group comprises a fluoroalcohol group, a carboxylic acid group, a sulfonimide group, a sulfonamide group, or carboximide group.

For example, the third repeating unit of the second polymer may be derived from one or more monomers of formulae (5a), (5b), (5c), or (5d):

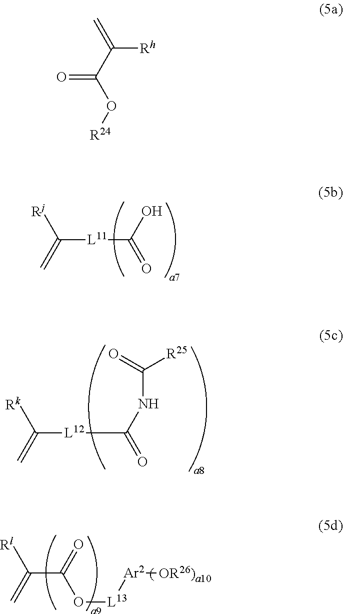

In formulae (5a), (5b), (5c), and (5d), R^{h}, R^{j}, R^{k}, and R^{l} are each independently hydrogen, halogen, or substituted or unsubstituted C₁₋₁₀ alkyl. Preferably, R^{h}, R^{j}, R^{k}, and R^{l} are each independently hydrogen, or substituted or unsubstituted C₁₋₅ alkyl, typically methyl.

In formula (5a), R²⁴ may be substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or substituted or unsubstituted poly(C₁₋₃ alkylene oxide). Preferably, the substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of halogen, a fluoroalcohol group (e.g., —C(CF₃)₂OH), a carboxylic acid group (e.g., —C(O)OH), a carboximide group (e.g., —(O)C—NH—C(O)—Y¹ where Y¹ is a divalent linking group or a terminal substituent group), a sulfonamide group (e.g., —S(O)₂NH—Y², where Y² is a divalent linking group or a terminal substituent group), or a sulfonimide group (e.g., —S(O)₂—NH—S(O)₂—Y³ where Y³ is a divalent linking group or a terminal substituent group).

In formulae (5b) and (5c), L¹¹ and L¹² each independently represents a single bond or a multivalent linking group chosen, for example, from optionally substituted aliphatic, such as C₁₋₆ alkylene or C₃₋₂₀ cycloalkylene, and aromatic hydrocarbons, and combinations thereof, optionally with one or more linking moieties chosen from —O—, —C(O)—, —C(O)O—, —S—, —S(O)₂—, —NR^{5a}—, or —C(O)N(R^{5b})—, wherein R^{5a} and R^{5b} are each independently chosen from hydrogen and optionally substituted C₁₋₁₀ alkyl. For example, the second polymer may include a repeating unit derived from one or more monomers of Formulae (5b) and/or (5c) wherein L¹¹ and/or L¹² are each independently a single bond or a multivalent linking group selected from substituted or unsubstituted C₁₋₂₀ alkylene, typically, C₁₋₆ alkylene; substituted or unsubstituted C₃₋₂₀ cycloalkylene; typically, C₃₋₁₀ cycloalkylene; and substituted or unsubstituted C₆₋₂₄ arylene.

In formulae (5b) and (5c), a7 and a8 are each independently an integer from 1 to 5, typically 1. It is to be understood that when a7 is 1, the group L¹¹ is a divalent linking group; when a7 is 2, the group L¹¹ is a trivalent linking group; when a7 is 3, the group L¹¹ is a tetravalent linking group; when a7 is 4, the group L¹¹ is a pentavalent linking group; and when a7 is 5, the group L¹¹ is a hexavalent linking group. Similarly, when a8 is 1, the group L¹² is a divalent linking group, when a8 is 2, the group L¹² is a trivalent linking group, when a8 is 3, the group L¹² is a tetravalent linking group, when a8 is 4, the group L¹² is a pentavalent linking group, and when a8 is 5, the group L¹² is a hexavalent linking group. Accordingly, in the context of formulae (5b) and (5c), the term “multivalent linking group” may refer to any of divalent, trivalent, tetravalent, pentavalent, and/or hexavalent linking groups.

In some aspects, when a7 is 2 or greater, the carboxylic acid groups (—C(O)OH) may be connected to the same atom of the linking group L¹¹. In other aspects, when a7 is 2 or greater, the carboxylic acid groups (—C(O)OH) may be connected to different atoms of the linking group L¹¹. In some aspects, when a8 is 2 or greater, the imide groups (—C(O)NHC(O)R²⁵) may be connected to the same atom of the linking group L¹². In other aspects, when a8 is 2 or greater, the imide groups (—C(O)NHC(O)R²⁵) may be connected to different atoms of the linking group L¹².

In formula (5c), each R²⁵ may independently be hydrogen or methyl.

In formula (5d), L¹³ represents a single bond or a divalent linking group. Preferably, L¹³ is a single bond, substituted or unsubstituted C₆₋₃₀ arylene, or substituted or unsubstituted C₆₋₃₀ cycloalkylene.

In formula (5d), a9 is 0 or 1. It is to be understood that when a9 is 0, the moiety represented by —OC(O)— is a single bond such that L¹³ is directly connected to the alkenyl (vinylic) carbon atom.

In formula (5d), Ar² is a substituted C₅₋₆₀ aromatic group that optionally includes one or more aromatic ring heteroatoms chosen from N, O, S, or a combination thereof, wherein the aromatic group may be monocyclic, non-fused polycyclic, or fused polycyclic. When the C₅₋₆₀ aromatic group is polycyclic, the ring or ring groups may be fused (such as naphthyl or the like), non-fused, or a combination thereof. When the polycyclic C₅₋₆₀ aromatic group is non-fused, the ring or ring groups may be directly linked or may be bridged by a heteroatom. In some aspects, the polycyclic C₅₋₆₀ aromatic group may include a combination of fused rings and directly linked rings.

In formula (5d), a10 may be an integer from 1 to 12, preferably from 1 to 6, and typically from 1 to 3.

Non-limiting examples of monomers of formulae (5a), (5b), (5c), and/or (5d) include one or more of the following:

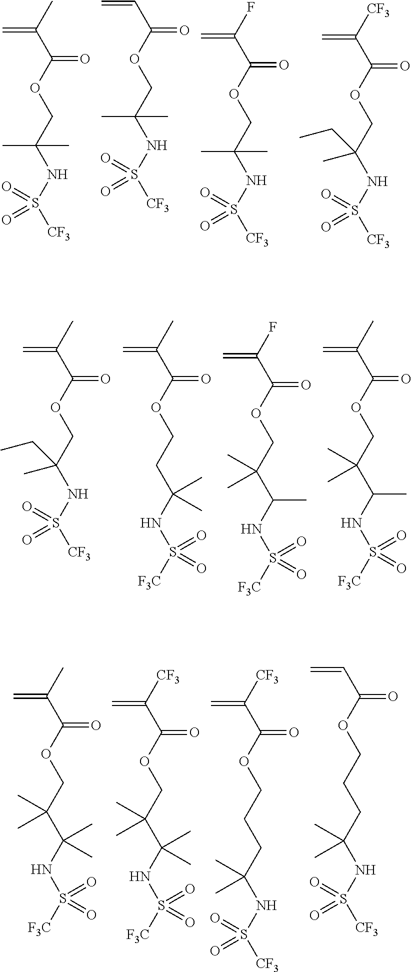

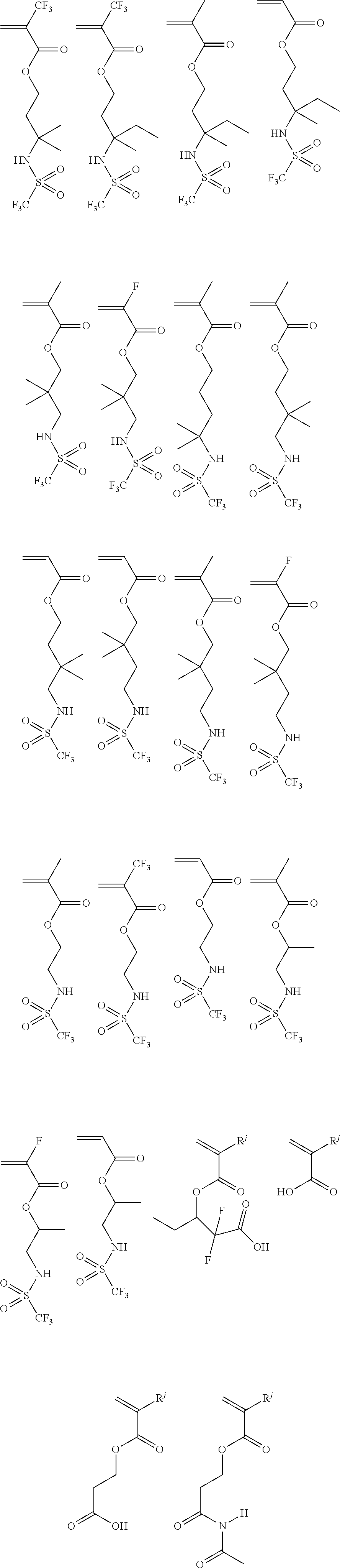

wherein R^{j} is as defined for formula (5b).

In one or more embodiments, the third repeating unit of the second polymer may be derived from a monomer of formula (1) or formula (3).

In some aspects, the third repeating unit of the second polymer may be derived from a monomer of formula (1), formula (3), formula (5a), formula (5b), formula (5c), or formula (5d). Preferably, the third repeating unit of the second polymer is derived from a monomer of formula (1) or formula (3).

The second polymer typically comprises the third repeating unit in an amount from 5 to 70 mol %, typically from 10 to 60 mol %, and more typically from 10 to 50 mol %, based on total moles of repeating units in the second polymer. Typically, when the third repeating unit is derived from a monomer of formula (1), it is present in an amount from 30 to 70 mol %, typically from 35 to 60 mol %, and more typically from 40 to 60 mol %, based on total moles of repeating units in the second polymer. Typically, when the third repeating unit is derived from a monomer of formula (3), formula (5a), formula (5b), formula (5c), and/or formula (5d), it may be present in an amount from 5 to 50 mol %, typically from 5 to 40 mol %, and more typically from 5 to 25 mol %, or from 5 to 20 mol %, or from 5 to 15 mol %, based on total moles of repeating units in the second polymer

Non-limiting exemplary second polymers of the present invention include one or more of the following:

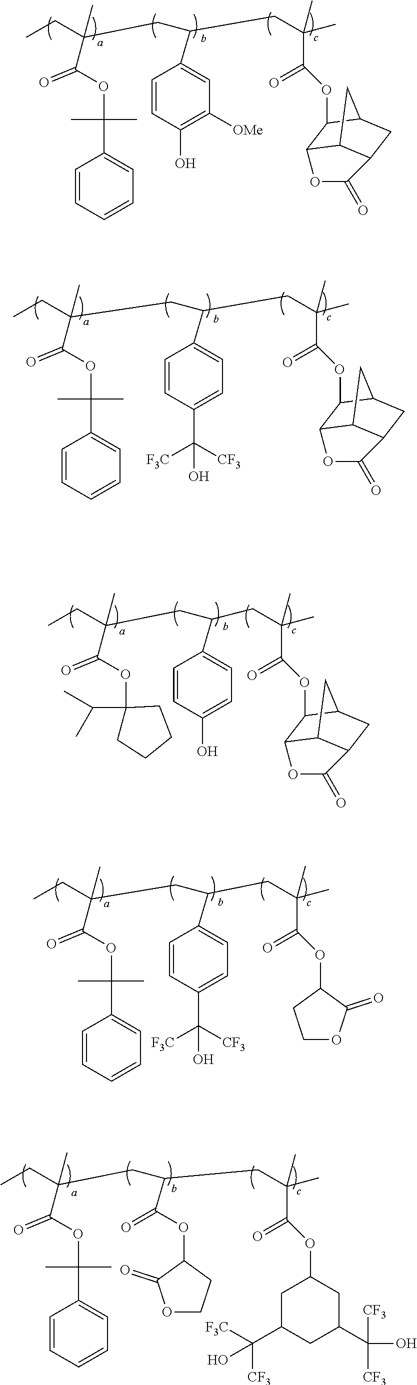

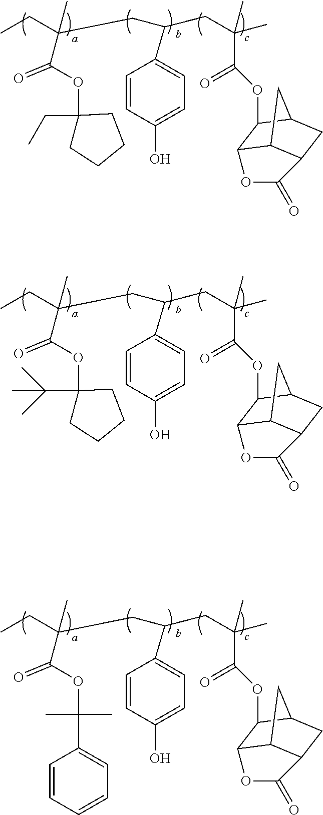

wherein a, b, and c each indicate the relative molar amounts of the respective repeating unit(s).

The second polymer typically has a M_{w} from 1,000 to 50,000 Da, preferably from 2,000 to 30,000 Da, more preferably 3,000 to 25,000 Da, and still more preferably from 4,000 to 15,000 Da. The PDI of the second polymer is typically from 1.1 to 3, and more typically from 1.1 to 2. Molecular weight values are determined by GPC using polystyrene standards.

The photoresist composition typically includes the first polymer and the second polymer in a weight ratio from 1:4 to 4:1, for example, from 1:4 to 4:1, or from 1:3 to 3:1, or from 1:2 to 2:1.

The first polymer and the second polymer each may further optionally include one or more additional repeating units. The additional repeating units may be, for example, one or more additional units for purposes of adjusting properties of the photoresist composition, such as etch rate and solubility. Exemplary additional units may include those derived from one or more of (meth)acrylate, vinyl aromatic, vinyl ether, vinyl ketone, and/or vinyl ester monomers. The one or more additional repeating units, if present in the first and/or second polymer, may be used in an amount of up to 50 mol %, typically from 3 to 50 mol %, based on total repeating units of the respective polymer.

The first and second polymers may be prepared using any suitable method(s) in the art. For example, one or more monomers corresponding to the repeating units described herein may be combined, or fed separately, using suitable solvent(s) and initiator, and polymerized in a reactor. For example, the polymers may be obtained by polymerization of the respective monomers under any suitable conditions, such as by heating at an effective temperature, irradiation with actinic radiation at an effective wavelength, or a combination thereof.

In some aspects, the photoresist composition further comprises a photoacid generator (PAG). Suitable PAGs can generate an acid that, during post-exposure bake (PEB), causes cleavage of acid-labile groups present on a polymer of the photoresist composition. The PAG may be in non-polymeric form or in polymeric form, for example, present in a polymerized repeating unit of the first and/or second polymers as described above, or as part of a different polymer. In some embodiments, the PAG may be included in the composition as a non-polymerized PAG compound, as a repeating unit of a polymer having a PAG moiety that is derived from a polymerizable PAG monomer, or as a combination thereof.

Suitable non-polymeric PAG compounds may have Formula G⁺A⁻, wherein G⁺ is an organic cation chosen from iodonium cations substituted with two alkyl groups, two aryl groups, or a combination of alkyl and aryl groups; and sulfonium cations substituted with three alkyl groups, three aryl groups, or a combination of alkyl and aryl groups, and A⁻ is a non-polymerizable organic anion. Particularly suitable non-polymeric organic anions include those, the conjugated acids of which have a pKa of from −15 to 1. Particularly preferred anions are fluorinated alkyl sulfonates and fluorinated sulfonimides.

Useful non-polymeric PAG compounds are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)acetate, and t-butyl α-(p-toluenesulfonyloxy)acetate; as described in U.S. Pat. Nos. 4,189,323 and 8,431,325.

Typically, when the photoresist composition includes a non-polymeric photoacid generator, it is present in the photoresist composition in an amount of from 0.1 to 65 wt %, more typically 1 to 20 wt %, based on total solids of the photoresist composition.

In some embodiments, G⁺ may be a sulfonium cation of formula (6a) or an iodonium cation of formula (6b):

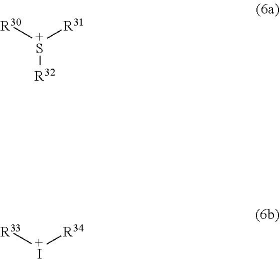

In formulae (6a) and (6b), R³⁰ to R³⁴ are each independently substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, or substituted or unsubstituted C₄₋₂₀ heteroarylalkyl. Each of R³⁰ to R³⁴ may be either separate or connected to another group R³⁰ to R³⁴ via a single bond or a divalent linking group to form a ring. Each of R³⁰ to R³⁴ optionally may include as part of its structure a divalent linking group. Each of R³⁰ to R³⁴ independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups.

Exemplary sulfonium cations of formula (6a) may include one or more of the following:

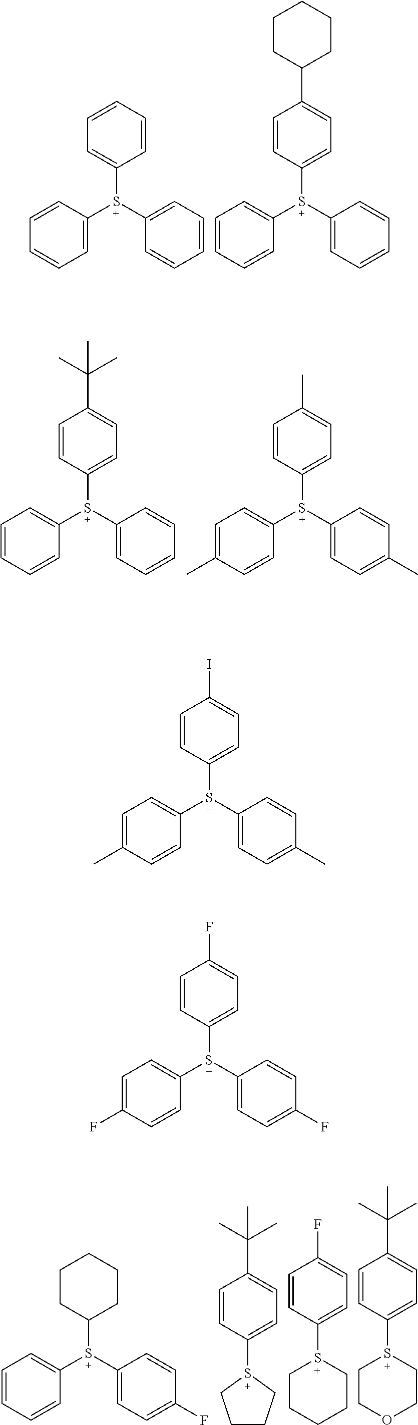

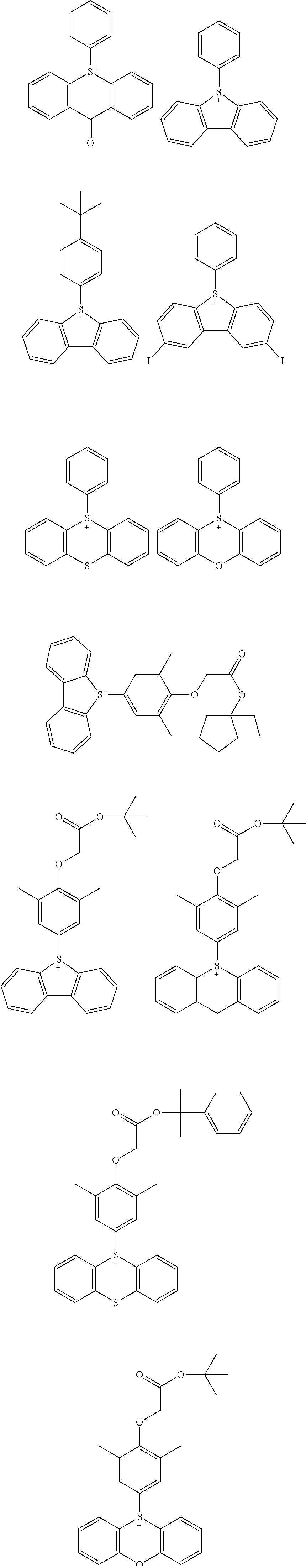

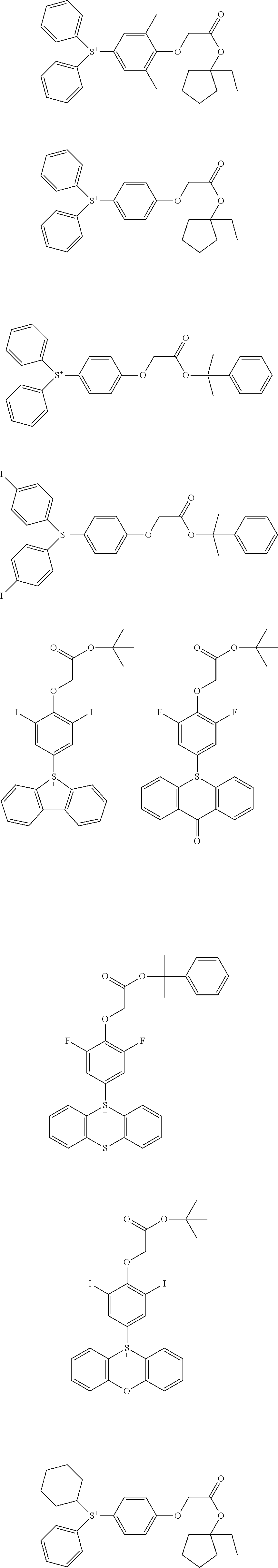

Exemplary iodonium cations of formula (6b) may include one or more of the following:

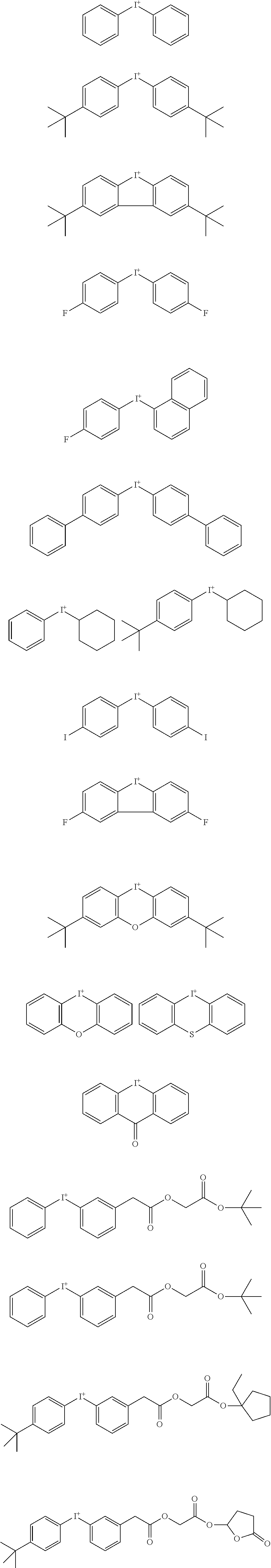

PAGs that are onium salts typically comprise an organic anion having a sulfonate group or a non-sulfonate-type group, such as sulfonamidate, sulfonimidate, methide, or borate.

Exemplary organic anions having a sulfonate group include one or more of the following:

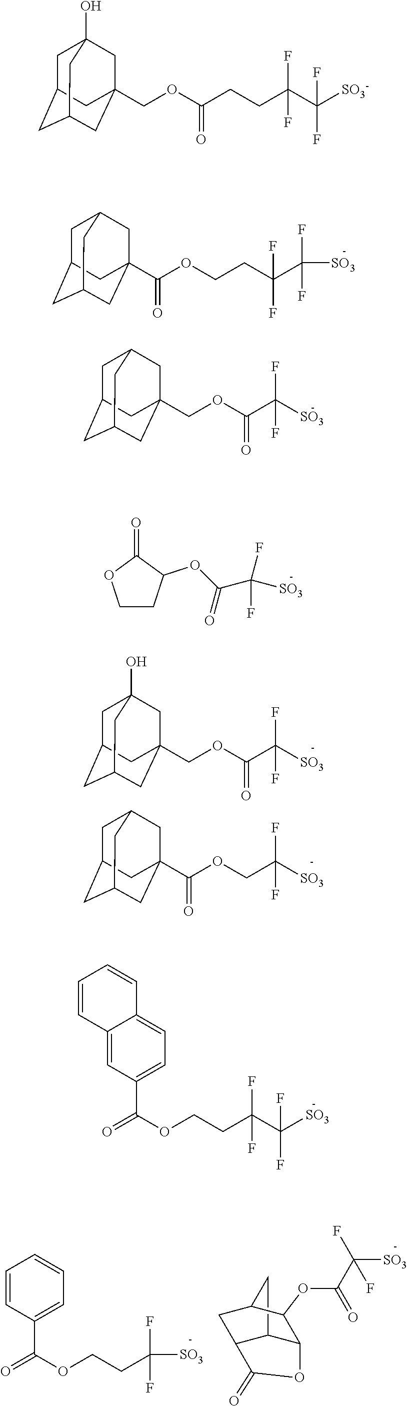

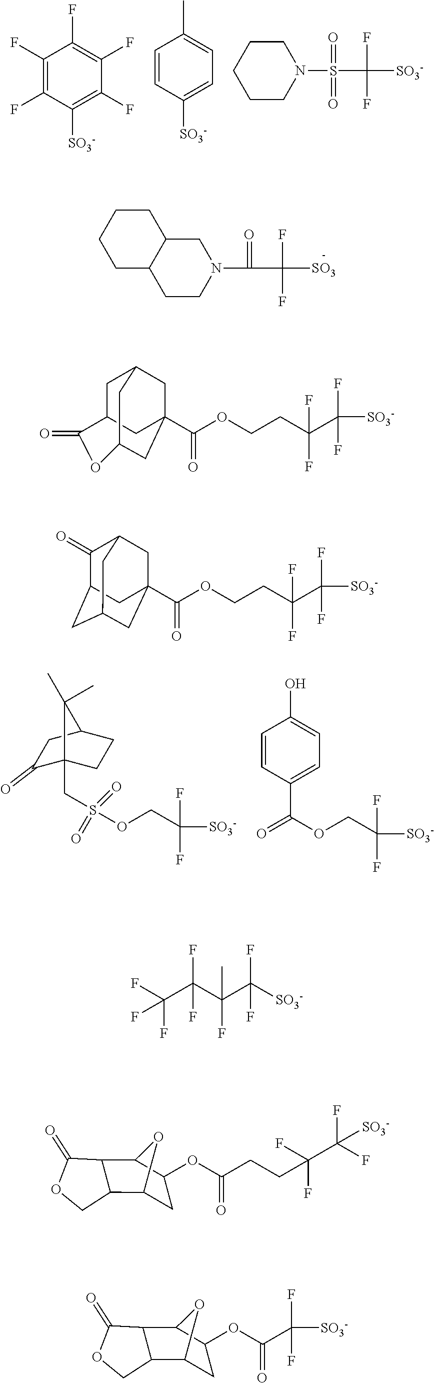

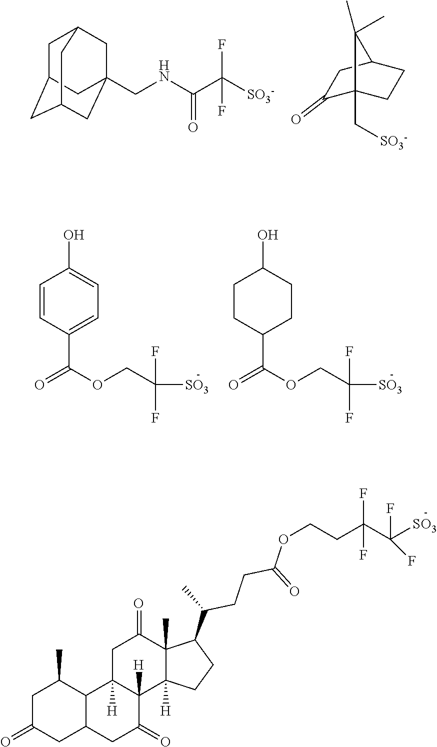

Exemplary non-sulfonated anions include one or more of the following:

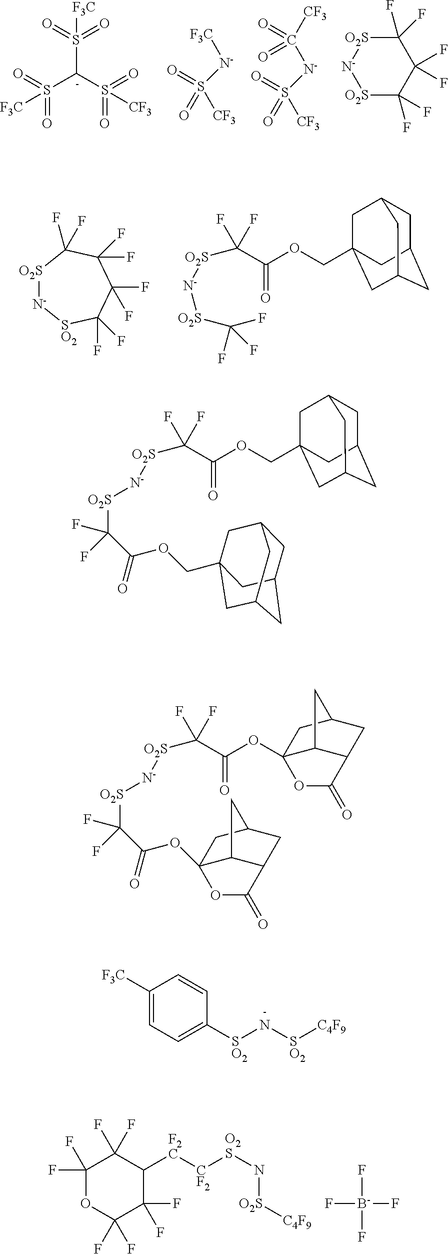

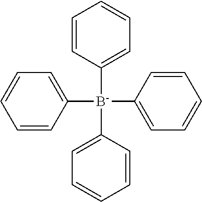 [SMILES: c1ccc([B-](c2ccccc2)(c2ccccc2)c2ccccc2)cc1]

The photoresist composition may optionally comprise a plurality of PAGs. The plurality of PAGs may be polymeric, non-polymeric, or may include both polymeric and non-polymeric PAGs. Preferably, each PAG of the plurality of PAGs is non-polymeric.

In one or more aspects, the photoresist composition may include a first photoacid generator that includes a sulfonate group on the anion, and the photoresist composition may include a second photoacid generator that is non-polymeric, wherein the second photoacid generator may include an anion that is free of sulfonate groups.

In some aspects, the polymer optionally may further include a repeating unit that comprises a PAG-containing moiety, for example a repeating unit derived from one or more monomers of formula (7):

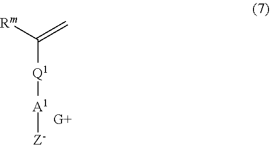

In formula (7), R^{m} may be hydrogen, halogen, or substituted or unsubstituted C₁₋₁₀ alkyl. Preferably, R^{m} is hydrogen, or substituted or unsubstituted C₁₋₅ alkyl, typically methyl.

In formula (7), Q¹ may be a single bond or a divalent linking group. Preferably, Q¹ includes 1 to 10 carbon atoms and at least one heteroatom, more preferably Q¹ is —C(O)—O—.

In formula (7), A¹ is a divalent linking group and, for example, may be one or more of substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, or substituted or unsubstituted C₃₋₃₀ heteroarylene. Preferably, A¹ may be a divalent C₁₋₃₀ perfluoroalkylene group that is optionally substituted.

In formula (7), Z⁻ is an anionic moiety, the conjugated acid of which typically has a pKa from −15 to 1. For example, Z⁻ may be a sulfonate, a carboxylate, an anion of a sulfonamide, an anion of a sulfonimide, or a methide anion. Particularly preferred anion moieties are fluorinated alkyl sulfonates and fluorinated sulfonimides.

In formula (7), G⁺ is an organic cation as defined above. In some embodiments, G⁺ is an iodonium cation substituted with two alkyl groups, two aryl groups, or a combination of alkyl and aryl groups; or a sulfonium cation substituted with three alkyl groups, three aryl groups, or a combination of alkyl and aryl groups.

Exemplary monomers of formula (7) may include one or more of the following:

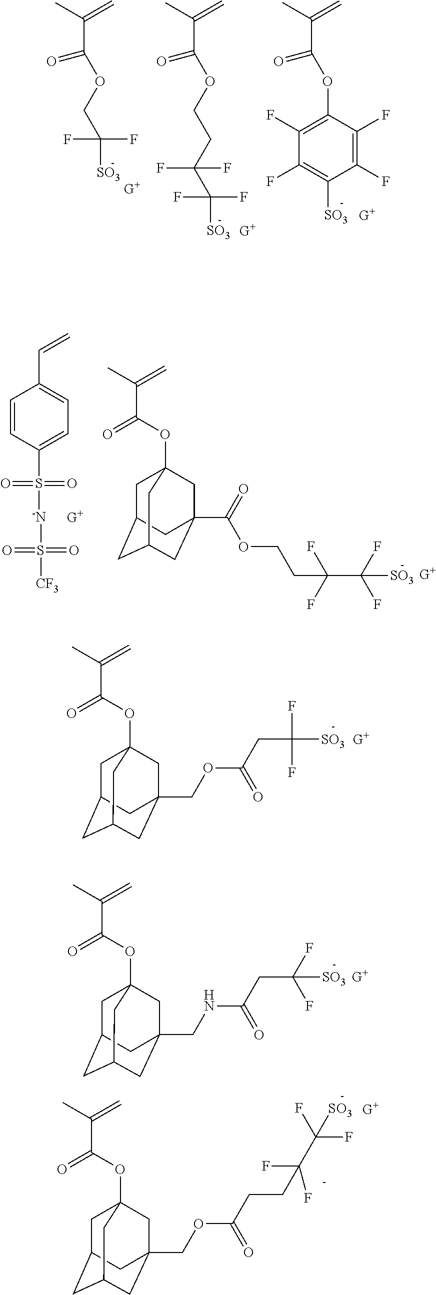

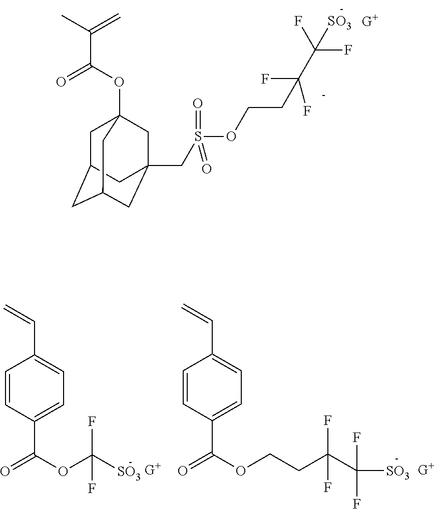

wherein G⁺ is an organic cation as defined herein.

When used, the repeating unit comprising a PAG moiety can be included in a polymer in an amount from 1 to 25 mol %, typically from 1 to 8 mol %, more typically from 2 to 6 mol %, based on total repeating units in the polymer.

The photoresist composition further includes a solvent for dissolving the components of the composition and to facilitate its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol, 4-methyl-2-pentanol, and diacetone alcohol (4-hydroxy-4-methyl-2-pentanone); propylene glycol monomethyl ether (PGME); ethers such as diethyl ether, tetrahydrofuran, 1,4-dioxane, and anisole; ketones such as acetone, methyl ethyl ketone, methyl iso-butyl ketone, 2-heptanone, and cyclohexanone (CHO); esters such as ethyl acetate, n-butyl acetate, propylene glycol monomethyl ether acetate (PGMEA), ethyl lactate (EL), hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents are PGME, PGMEA, EL, GBL, HBM, CHO, and combinations thereof.

The total solvent content (i.e., cumulative solvent content for all solvents) in the photoresist compositions is typically from 40 to 99 wt %, for example, from 60 to 99 wt %, or from 85 to 99 wt %, based on total solids of the photoresist composition. The desired solvent content will depend, for example, on the desired thickness of the coated photoresist layer and coating conditions.

In the photoresist compositions of the invention, the first polymer and the second polymer are typically present together in the photoresist composition in an amount of from 10 to 99.9 wt %, typically from 25 to 99 wt %, and more typically from 50 to 95 wt %, based on total solids of the photoresist composition. It will be understood that total solids includes the first and second polymers, optional PAGs, and other non-solvent components.

In some aspects, the photoresist composition may further include a material that comprises one or more base-labile groups (a “base-labile material”). As referred to herein, base-labile groups are functional groups that can undergo cleavage reaction to provide polar groups such as hydroxyl, carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the photoresist composition that comprises the base-labile group. Thus, for instance, a base-labile group will be substantially inert during pre-exposure soft-bake, exposure, and post-exposure bake steps. By “substantially inert” it is meant that typically of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26N aqueous solution of TMAH may be used for single puddle development or dynamic development, e.g., where the 0.26N TMAH developer is dispensed onto an imaged photoresist layer for a suitable time such as 10 to 120 seconds (s). An exemplary base-labile group is an ester group, typically a fluorinated ester group. Preferably, the base-labile material is substantially not miscible with and has a lower surface energy than the first and/or second polymers and other solid components of the photoresist composition. When coated on a substrate, the base-labile material can thereby segregate from other solid components of the photoresist composition to a top surface of the formed photoresist layer.

In some aspects, the base-labile material may be a polymeric material, also referred to herein as a base-labile polymer, which may include one or more repeating units comprising one or more base-labile groups. For example, the base-labile polymer may comprise a repeating unit comprising 2 or more base-labile groups that are the same or different. A preferred base-labile polymer includes at least one repeating unit comprising 2 or more base-labile groups, for example a repeating unit comprising 2 or 3 base-labile groups.

The base-labile polymer may be a polymer comprising a repeating unit derived from one or more monomers of formula (8):

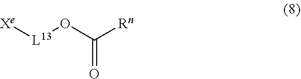

wherein X^{e} is a polymerizable group selected from C₂ alkenyl and (meth)acrylic, L¹³ is a divalent linking group; and Rⁿ is substituted or unsubstituted C₁₋₂₀ fluoroalkyl, provided that the carbon atom bonded to the carbonyl (—C(O)—) in formula (8) is substituted with at least one fluorine atom. Exemplary monomers of formula (8) may include one or more of the following:

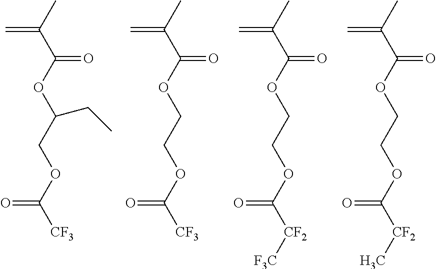

The base-labile polymer may include a repeating unit including two or more base-labile groups. For example, the base-labile polymer can include a repeating unit derived from one or more monomers of formula (9):

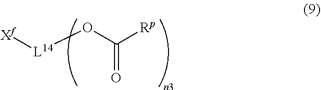

wherein X^{f} Valid R^{p} are as defined in formula (8) for X^{e} and Rⁿ, respectively; L¹⁴ is a polyvalent linking group including one or more of substituted or unsubstituted C₁₋₂₀ alkylene, substituted or unsubstituted C₃₋₂₀ cycloalkylene, —C(O)—, or —C(O)O—; and n3 may be an integer of 2 or greater, for example 2 or 3. Exemplary monomers of formula (9) may include one or more of the following:

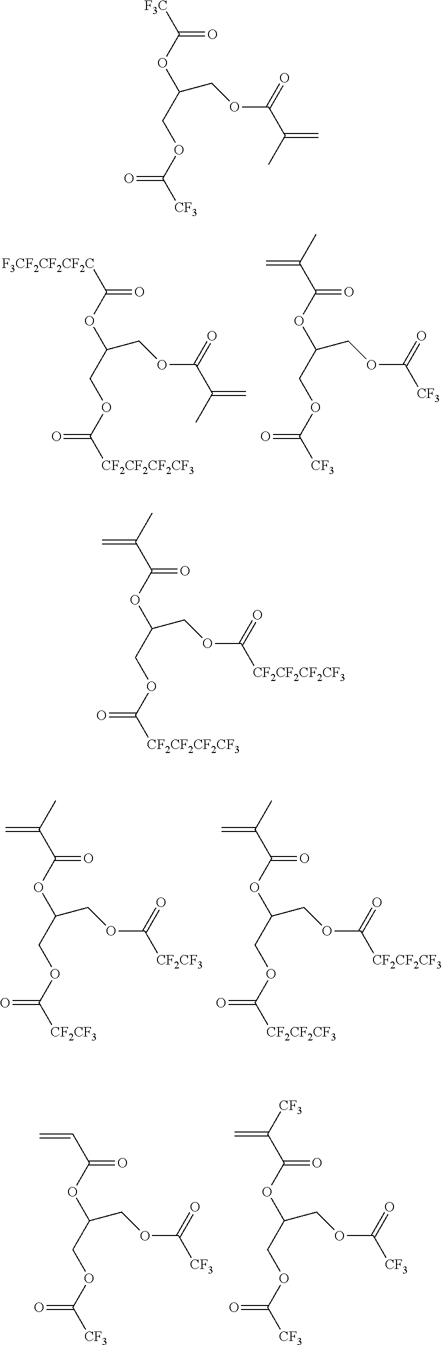

The base-labile polymer may include a repeating unit including one or more base-labile groups. For example, the base-labile polymer can include a repeating unit derived from one or more monomers of formula (10):

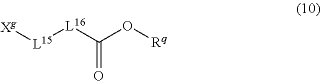

wherein X^{g} and R^{q} are as defined in formula (10) for X^{e} and Rⁿ, respectively; L¹⁵ is a divalent linking group; and L¹⁶ is substituted or unsubstituted C₁₋₂₀ fluoroalkylene wherein the carbon atom bonded to the carbonyl (—C(O)—) in formula (10) is substituted with at least one fluorine atom. Exemplary monomers of formula (10) may include one or more of the following:

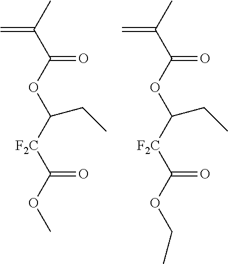 [SMILES: C=C(C)C(=O)OC(CC)C(F)(F)C(=O)OC ; C=C(C)C(=O)OC(CC)C(F)(F)C(=O)OCC]

In some aspects, a base-labile polymer may comprise one or more base-labile groups and one or more acid-labile groups, such as one or more acid-labile ester moieties (e.g., t-butyl ester) or acid-labile acetal groups. For example, the base-labile polymer may comprise a repeating unit including a base-labile group and an acid-labile group, i.e., wherein both a base-labile group and an acid-labile group are present on the same repeating unit. In another example, the base-labile polymer may comprise a first repeating unit comprising a base-labile group and a second repeating unit comprising an acid-labile group. Preferred photoresists of the invention can exhibit reduced defects associated with a resist relief image formed from the photoresist composition.

The base-labile polymer may be prepared using any suitable methods in the art, including those described herein for the first and second polymers. For example, the base-labile polymer may be obtained by polymerization of the respective monomers under any suitable conditions, such as by heating at an effective temperature, irradiation with actinic radiation at an effective wavelength, or a combination thereof. Additionally, or alternatively, one or more base-labile groups may be grafted onto the backbone of a polymer using suitable methods.

In some aspects, the base-labile material is a single molecule comprising one more base-labile ester groups, preferably one or more fluorinated ester groups. The base-labile materials that are single molecules typically have a M_{w} in the range from 50 to 1,500 Da. Exemplary base-labile materials include one or more of the following:

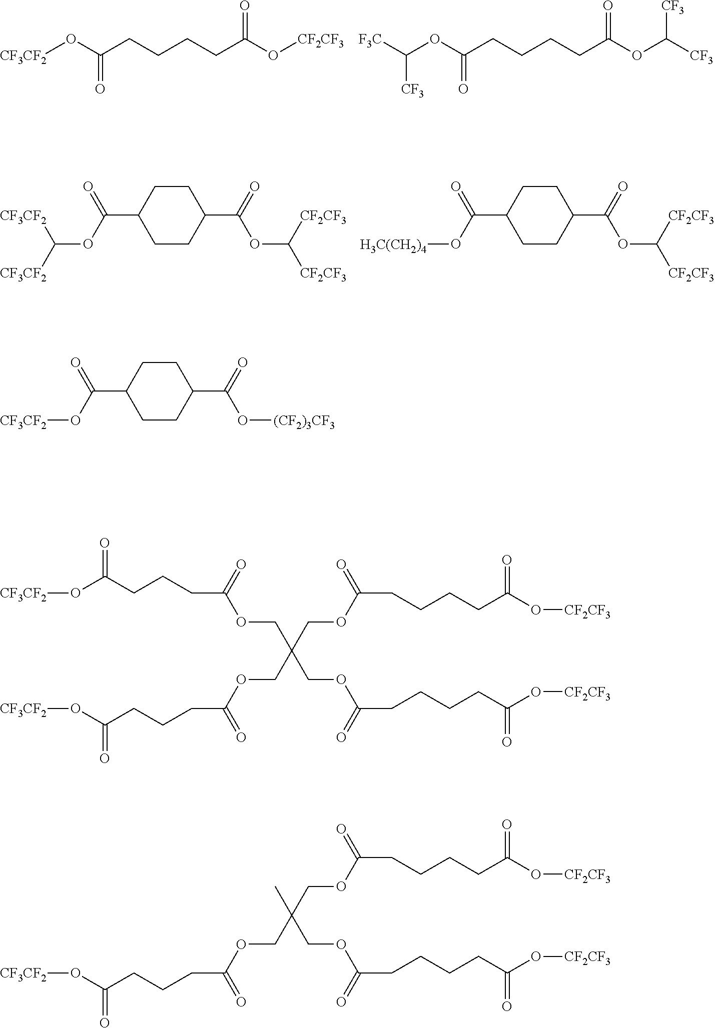

When present, the base-labile material is typically present in the photoresist compositions in an amount of from 0.01 to 10 wt %, typically 1 to 5 wt %, based on total solids of the photoresist composition.

Additionally, or alternatively, to the base-labile polymer, the photoresist compositions may further include one or more polymers in addition to and different from the first polymer and the second polymer as described above. For example, the photoresist compositions may include an additional polymer as described above but different in composition, or a polymer that is similar to those described above but does not include each of the requisite repeating units. Additionally, or alternatively, the one or more additional polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The photoresist composition may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the photoresist compositions in an amount of from 0.01 to 10 wt %, based on total solids of the photoresist composition.

PDQs generate a weak acid upon irradiation. The acid generated from a photo-decomposable quencher is not strong enough to react rapidly with acid-labile groups that are present in the resist matrix. Exemplary photo-decomposable quenchers include, for example, photo-decomposable cations, and preferably those also useful for preparing strong acid generator compounds, paired with an anion of a weak acid (pKa>1) such as, for example, an anion of a C₁₋₂₀ carboxylic acid or C₁₋₂₀ sulfonic acid. Exemplary carboxylic acids include formic acid, acetic acid, propionic acid, tartaric acid, succinic acid, cyclohexanecarboxylic acid, benzoic acid, salicylic acid, and the like. Exemplary sulfonic acids include p-toluene sulfonic acid, camphor sulfonic acid and the like. In a preferred embodiment, the photo-decomposable quencher is a photo-decomposable organic zwitterion compound such as diphenyliodonium-2-carboxylate.

The photo-decomposable quencher may be in non-polymeric or polymer-bound form. When in polymeric form, the photo-decomposable quencher is present in polymerized units on the first polymer or second polymer. The polymerized units containing the photo-decomposable quencher are typically present in an amount from 0.1 to 30 mole %, preferably from 1 to 10 mole % and more preferably from 1 to 2 mole %, based on total repeating units of the polymer.

Exemplary basic quenchers include, for example, linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher may be present in repeating units of the polymer. The repeating units containing the quencher are typically present in an amount of from 0.1 to 30 mole %, preferably from 1 to 10 mole % and more preferably from 1 to 2 mole %, based on total repeating units of the polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the photoresist composition further includes a surfactant polymer including a fluorine-containing repeating unit.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP™ 3000, AP™ 8000, and AP™ 9000S designations, available from DuPont Electronics & Industrial (Marlborough, Mass.).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, 1,000 to 2,500 rpm, for a period from 15 to 120 seconds to obtain a layer of the photoresist composition on the substrate. It will be appreciated by those skilled in the art that the thickness of the coated layer may be adjusted by changing the spin speed and/or the total solids of the composition. A photoresist composition layer formed from the compositions of the invention typically has a dried layer thickness from 3 to 30 micrometers (μm), preferably from greater than 5 to 30 μm, and more preferably from 6 to 25 μm.

The photoresist composition is typically next soft-baked to minimize the solvent content in the layer, thereby forming a tack-free coating and improving adhesion of the layer to the substrate. The soft bake is performed, for example, on a hotplate or in an oven, with a hotplate being typical. The soft bake temperature and time will depend, for example, on the photoresist composition and thickness. The soft bake temperature is typically from 80 to 170° C., and more typically from 90 to 150° C. The soft bake time is typically from 10 seconds to 20 minutes, more typically from 1 to 10 minutes, and still more typically from 1 to 2 minutes. The heating time can be readily determined by one of ordinary skill in the art based on the ingredients of the composition.

The photoresist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nm, sub-300 nm or sub-200 nm, with 248 nm (KrF), 193 nm (ArF), 13.5 nm (EUV) wavelengths or e-beam lithography being preferred. Preferably, the activating radiation is 248 nm radiation. The methods find use in immersion or dry (non-immersion) lithography techniques. The exposure energy is typically from 1 to 200 millijoules per square centimeter (mJ/cm²), preferably from 10 to 100 mJ/cm² and more preferably from 20 to 50 mJ/cm², dependent upon the exposure tool and components of the photoresist composition.

Following exposure of the photoresist layer, a post-exposure bake (PEB) of the exposed photoresist layer is performed. The PEB can be conducted, for example, on a hotplate or in an oven, with a hotplate being typical. Conditions for the PEB will depend, for example, on the photoresist composition and layer thickness. The PEB is typically conducted at a temperature from 70 to 150° C., preferably from 75 to 120° C., and a time from 30 to 120 seconds. A latent image defined by the polarity-switched (exposed regions) and unswitched regions (unexposed regions) is formed in the photoresist.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 98 wt % or more, or 100 wt %, based on total weight of the developer. Suitable organic solvents for the NTD developer include, for example, those chosen from ketones, esters, ethers, hydrocarbons, and mixtures thereof. The developer is typically 2-heptanone or n-butyl acetate.

A coated substrate may be formed from the photoresist compositions of the invention. Such a coated substrate includes: (a) a substrate having one or more layers to be patterned on a surface thereof; and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following non-limiting examples.

### EXAMPLES

### Example 1

This example describes the general synthesis of polymers P1-A to P1-G, P2-A to P2-P2-H, and P3-A to P3-B. The following monomers represent one or more of the structures that were used to prepare each of the comparative polymers and inventive polymers.

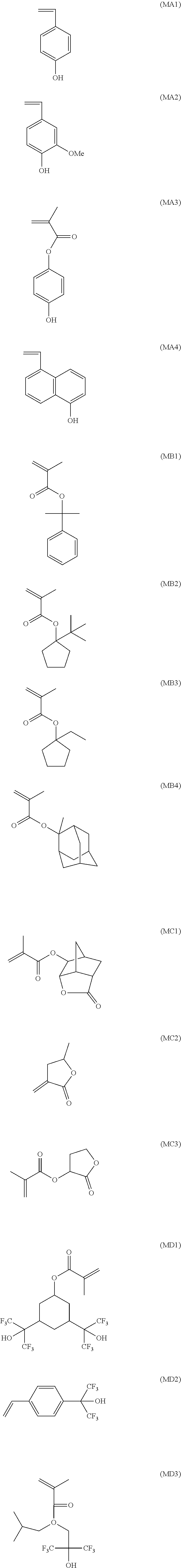

Polymer P1-A was prepared from the monomers MA1, MB1, and MD1, at a molar feed ratio of 45/45/10. A feed solution was made by dissolving MA1 (35.3 grams (g), 218 millimoles (mmol)), MB1 (44.5 g, 218 mmol), and MC1 (24.2 g, 48 mmol) in 104 g of PGMEA. An initiator solution was separately prepared by dissolving 6.6 g of the azo initiator (dimethyl 2,2′-azo-bis(2-methylpropionate), obtained as V-601 from Wako Pure Chemical Industries, Ltd.) in 19.8 g of PGMEA/tetrahydrofuran (THF) (1:1 by wt %) mixture.

The polymerization was performed in a 3-neck round bottom flask fitted with a water condenser and a thermometer to monitor the reaction in the flask. The reactor was charged with 53.3 g of PGMEA and heated to 75° C. The feed solution and the initiator solution were each fed into the reactor using syringe pumps over 4 hours. The contents were then stirred for an additional 2 hours. The contents were subsequently cooled to room temperature, diluted with 40 g of THF, and precipitated into 3 L of a 7:3 (v/v) mixture of heptane and isopropanol. The resulting polymer was isolated by filtration. The polymer was dried overnight at 35° C. under vacuum. The polymer obtained was then dissolved in methanol (312 g) to which sodium methoxide (0.333 g, 25 wt % in methanol) was added. The reaction mixture was heated at 67° C. The reaction was then allowed to cool to room temperature and neutralized with the addition of acid. The polymer solution was precipitated into deionized (DI) water to isolate a white solid polymer P1-A (about 62 g) (Mw=8.5 kDa, PDI=1.55) which was further dried under vacuum at 35° C.

Each of the polymers in Table 1 was prepared using a similar procedure to that described above for the preparation of polymer P1-A, except that the monomers and molar feed ratios as specified in Table 1 were used.

TABLE 1

| | Monomer 1 | Monomer 2 | Monomer 3 | Mw | |
|---|---|---|---|---|---|
| Polymer | (mol %) | (mol %) | (mol %) | (kD) | PDI |
| P1-A | MA1 (45) | MB1 (45) | MD1 (10) | 8.5 | 1.55 |
| P1-B | MA1 (45) | MB3 (45) | MD1 (10) | 8.5 | 1.66 |
| P1-C | MA2 (50) | MB1 (40) | MD1 (10) | 7.5 | 1.63 |
| P1-D | MA1 (45) | MB1 (45) | MD3 (10) | 7.6 | 1.72 |
| P1-E | MA1 (45) | MB1 (45) | MD2 (10) | 7.6 | 1.61 |
| P1-F | MA1 (45) | MB2 (45) | MD1 (10) | 6.5 | 1.56 |
| P1-G | MA1 (30) | MB1 (60) | MD2 (10) | 7.1 | 1.6 |
| P2-A | MB1 (45) | MC3 (45) | MD1 (10) | 7.2 | 1.60 |
| P2-B | MA1 (50) | MB1 (40) | MC1 (10) | 7.3 | 1.65 |
| P2-C | MA3 (50) | MB1 (40) | MC1 (10) | 12.3 | 2.08 |
| P2-D | MA2 (50) | MB1 (40) | MC1 (10) | 8.5 | 1.72 |
| P2-E | MA1 (50) | MB1 (40) | MC2 (10) | 7.1 | 1.68 |
| P2-F | MA1 (50) | MB2 (40) | MC1 (10) | 6.8 | 1.67 |
| P2-G | MB2 (45) | MC3 (45) | MD3 (10) | 7.2 | 1.66 |
| P2-H | MB3 (45) | MC3 (45) | MD1 (10) | 7.8 | 1.67 |
| P3-A | MA1 (60) | MB4 (40) | — | 8.4 | 1.64 |
| P3-B | MB1 (60) | MD2 (40) | — | 8.7 | 1.48 |
| P3-C | MA1 (40) | MB1 (60) | — | 7.2 | 1.63 |

### Photoresist Compositions and Evaluation

### Example 2

Photoresist compositions using the polymers from Table 1 were prepared by combining the components indicated in Table 2, where the amounts are expressed in weight percent (wt %) based on 100 wt % of total weight of the compositions. The total solids content for the photoresist compositions was 1.55 wt %. The photoresist compositions were prepared in a solvent mixture of propylene glycol monomethyl ether acetate (PGMEA) and methyl-2-hydroxyisobutyrate in a weight ratio of 1:1.

The resulting photoresist compositions were shaken on a mechanical shaker and then filtered through a PTFE disk-shaped filter having a 0.2-micron pore size. 200 mm silicon wafers overcoated with a BARC stack (60 nm-thickness AR™3 antireflectant over an 80 nm-thickness AR™40A antireflectant (DuPont Electronics & Industrial) were each spin-coated with a respective photoresist composition on a TEL Clean Track ACT 8 wafer track and softbaked at 110° C. for 60 seconds to provide a photoresist layer with a target thickness of about 100 nm. The resist layer thickness was measured with a THERMA-WAVE OP7350. The wafers were exposed with 248 nm radiation (CANON FPA-5000 ES4 scanner) at increasing exposure dose from 3 to 53 millijoules per square centimeter (mJ/cm²). The wafers were then subjected to post-exposure bake (PEB) at 100° C. for 60 seconds, developed with MF™-CD26 TMAH developer (DuPont Electronics & Industrial) for 60 seconds, rinsed with DI water, and dried. Photoresist layer thickness measurements were made in exposed and unexposed regions of the layer. A contrast curve for each wafer was generated by plotting the remaining photoresist layer thickness in the exposed regions versus dose. Dose-to-clear (E₀) was determined from the contrast curve as the exposure dose at which the remaining photoresist layer thickness was less than 10% of the original coated thickness. An additional contrast curve for each wafer was generated by plotting normalized photoresist layer thickness in the exposed regions vs. Log dose. Contrast (gamma, γ) was determined from the contrast curve as the slope between the point of 80% and 20% photoresist film thickness.

TABLE 2

| Composition | P1 | P2 | P3 | PAG | Additive | E₀ (mJ/cm²) | Gamma (γ) |
|---|---|---|---|---|---|---|---|
| PR-1 | P1-A | P2-A | — | PAG 1 | Q1 | 9.3 | 19.8 |
| | (0.4261) | (0.4261) | | (0.1278) | (0.02) | | |
| PR-2 | P1-B | P2-B | — | PAG 1 | Q1 | 8.6 | 20.9 |
| | (0.4261) | (0.4261) | | (0.1278) | (0.02) | | |
| PR-3 | P1-C | P2-B | — | PAG 1 | Q1 | 8.4 | 10.7 |
| | (0.4261) | (0.4261) | | (0.1278) | (0.02) | | |
| PR-4 | P1-D | P2-A | — | PAG 1 | Q1 | 8.9 | 17.3 |
| | (0.4261) | (0.4261) | | (0.1278) | (0.02) | | |
| PR-5 | P1-F | P2-C | — | PAG 1 | Q1 | 9.3 | 12.3 |
| | (0.4261) | (0.4261) | | (0.1278) | (0.02) | | |
| PR-6 | P1-B | P2-F | — | PAG 1 | Q1 | 8.9 | 16.9 |
| | (0.4261) | (0.4261) | | (0.1278) | (0.02) | | |
| PR-7 | P1-B | P2-G | — | PAG 1 | Q1 | 9.0 | 24.8 |
| | (0.4261) | (0.4261) | | (0.1278) | (0.02) | | |
| PR-8 | P1-B | P2-H | — | PAG 1 | Q1 | 9.1 | 15.4 |
| | (0.4261) | (0.4261) | | (0.1278) | (0.02) | | |
| PR-9 | P1-G | P2-D | — | PAG 1 | Q1 | 8.5 | 16.6 |
| | (0.4261) | (0.4261) | | (0.1278) | (0.02) | | |
| PR-10 | P1-G | P2-B | — | PAG 1 | Q1 | 9.2 | 10.2 |
| | (0.4261) | (0.4261) | | (0.1278) | (0.02) | | |
| PR-11* | P1-A | — | P3-A | PAG 1 | Q1 | 11.1 | 8.4 |
| | (0.4261) | | (0.4261) | (0.1278) | (0.02) | | |
| PR-12* | P1-G | — | P3-B | PAG 1 | Q1 | 9.8 | 6.8 |
| | (0.4261) | | (0.4261) | (0.1278) | (0.02) | | |
| PR-13* | P1-A | — | P3-C | PAG 1 | Q1 | 9.3 | 9.4 |
| | (0.4261) | | (0.4261) | (0.1278) | (0.02) | | |
| PR-14* | P1-G | — | — | PAG 1 | Q1 | 10.0 | 7.3 |
| | (0.8522) | | | (0.1278) | (0.02) | | |
| PR-15* | — | P2-D | — | PAG 1 | Q1 | 8.5 | 9.5 |
| | | (0.8522) | | (0.1278) | (0.02) | | |

*denotes a comparative photoresist composition

The structures of the PAG (PAG-1) and the additive (Q1) were as follows:

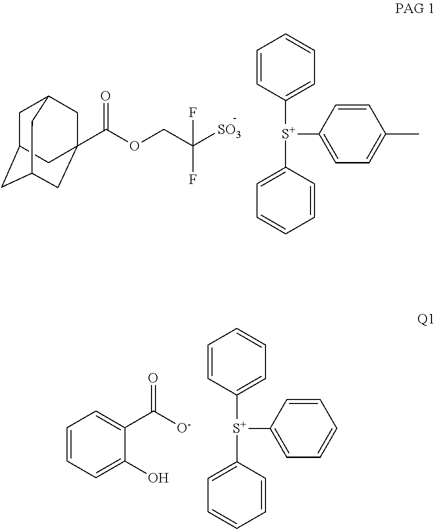

As shown in Table 2, the inventive photoresist compositions PR-1 to PR-10 achieved improved contrast (higher gamma values) and a comparable or improved sensitivity (decreased E₀ values) relative to the comparative photoresist compositions PR-11 to PR-15. The inventive photoresist composition PR-1, which included P1-A and P2-A, achieved improved contrast and demonstrated a comparable or better sensitivity relative to comparative photoresist compositions PR-11 and PR-13, which included polymer P3-A or P3-C, respectively, instead of polymer P2-A. The inventive photoresist composition PR-9, which included polymers P1-G and P2-D, achieved improved contrast and demonstrated a comparable or better sensitivity relative to photoresist compositions PR-14 and PR-15, which included polymer P1-G or P2-D, respectively, and did not include a second polymer. The observed contrast (γ) of photoresist composition PR-9 exceeds the contrast (γ) that would have been expected for the additive combination of polymers P1-G and P2-D, and therefore demonstrates that a synergistic improvement to contrast (γ) was achieved by the combination of the inventive polymers of the photoresist composition.

### Example 3

The photoresist compositions were evaluated for line/space patterning under KrF exposure using a bright field mask pattern. 200 mm silicon wafers overcoated with a BARC stack (60 nm thickness AR™3 antireflectant followed by 80 nm thickness AR™40A antireflectant [DuPont Electronics & Industrial]) were each spin-coated with a respective photoresist composition on a TEL Clean Track ACT 8 wafer track and softbaked at 110° C. for 60 seconds to provide a photoresist layer with a thickness of about 40 nm. The wafers were each exposed with 248 nm radiation on a CANON FPA-5000 ES4 scanner (NA=0.8, outer sigma=0.85, inner sigma=0.57) using a mask having 120 nm line/space (L/S) patterns. The wafers were post-exposure baked at 100° C. for 60 seconds, developed with MF™-CD26 TMAH developer (DuPont Electronics & Industrial) for 60 seconds, rinsed with DI water, and dried. Critical dimension (CD) measurements of the formed L/S patterns were made with a HITACHI S-9380 CD SEM. Sizing energy (E_{size}), and line width roughness (LWR) of the lines were determined based on the CD measurements. Sizing energy is the irradiation energy at which the target 120 nm L/S pattern was resolved.

The results are shown in Table 3.

TABLE 3

| Composition | P1 | P2 | P3 | PAG | Additive | E_{size} (mJ/cm²) | LWR (nm) |
|---|---|---|---|---|---|---|---|
| PR-16 | P1-A | P2-A | — | PAG1 | Q1 | 43.492 | 18.43 |
| | (0.4261) | (0.4261) | | (0.1278) | (0.02) | | |
| PR-17 | P1-C | P2-B | — | PAG1 | Q1 | 40.714 | 17.19 |
| | (0.4261) | (0.4261) | | (0.1278) | (0.02) | | |
| PR-18 | P1-E | P2-A | — | PAG1 | Q1 | 42.294 | 18.23 |
| | (0.4261) | (0.4261) | | (0.1278) | (0.02) | | |
| PR-19 | P1-G | P2-D | — | PAG1 | Q1 | 40.442 | 16.45 |
| | (0.4261) | (0.4261) | | (0.1278) | (0.02) | | |
| PR-20 | P1-G | P2-B | — | PAG1 | Q1 | 44.053 | 15.31 |
| | (0.4261) | (0.4261) | | (0.1278) | (0.02) | | |
| PR-21* | P1-A | — | P3-A | PAG1 | Q1 | 54.138 | 22.5 |
| | (0.4261) | | (0.4261) | (0.1278) | (0.02) | | |
| PR-22* | P1-G | — | P3-B | PAG1 | Q1 | 44.905 | 18.97 |
| | (0.4261) | | (0.4261) | (0.1278) | (0.02) | | |

*denotes a comparative photoresist composition

As can be seen in Table 3, the inventive photoresist compositions PR-16 to PR-20 achieved improved pattern roughness (i.e., a decreased LWR) and an improved sensitivity (decreased E_{size}) relative to comparative photoresist compositions PR-21 and PR-22.

### Example 4

The photoresist compositions of Table 4 were evaluated for line/space (L/S) patterning under KrF exposure as described above and using a dark field mask pattern. Sizing energy (E_{size}), and line width roughness (LWR) of the spaces were determined based on the CD measurements. Sizing energy was determined from the irradiation energy at which the target 120 nm L/S pattern was resolved. The results are shown in Table 4.

TABLE 4

| Composition | P1 | P2 | P3 | PAG | Additive | E_{size} (mJ/cm²) | LWR (nm) |
|---|---|---|---|---|---|---|---|
| PR-23 | P1-A | P2-A | — | PAG 1 | Q1 | 45.051 | 16.45 |
| | (0.4261) | (0.4261) | | (0.1278) | (0.02) | | |
| PR-24 | P1-B | P2-B | — | PAG 1 | Q1 | 43.213 | 15.17 |
| | (0.4261) | (0.4261) | | (0.1278) | (0.02) | | |
| PR-25 | P1-C | P2-B | — | PAG 1 | Q1 | 42.169 | 14.39 |
| | (0.4261) | (0.4261) | | (0.1278) | (0.02) | | |
| PR-26 | P1-D | P2-A | — | PAG 1 | Q1 | 45.180 | 14.67 |
| | (0.4261) | (0.4261) | | (0.1278) | (0.02) | | |
| PR-27 | P1-E | P2-A | — | PAG 1 | Q1 | 44.333 | 14.61 |
| | (0.4261) | (0.4261) | | (0.1278) | (0.02) | | |
| PR-28 | P1-G | P2-D | — | PAG 1 | Q1 | 46.333 | 12.61 |
| | (0.4261) | (0.4261) | | (0.1278) | (0.02) | | |
| PR-29* | P1-A | — | P3-A | PAG 1 | Q1 | 55.944 | 21.9 |
| | (0.4261) | | (0.4261) | (0.1278) | (0.02) | | |
| PR-30* | P1-G | — | P3-B | PAG 1 | Q1 | 54.177 | 18.28 |
| | (0.4261) | | (0.4261) | (0.1278) | (0.02) | | |
| PR-31* | P1-A | — | P3-C | PAG 1 | Q1 | 47.106 | 18.2 |
| | (0.4261) | | (0.4261) | (0.1278) | (0.02) | | |

*denotes a comparative photoresist composition

As shown above, the inventive photoresist compositions PR-23 to PR-28 achieved improved pattern roughness (i.e., a decreased LWR) and an improved sensitivity (i.e., a decreased E_{size}) relative to the comparative photoresist compositions PR-29 to PR-31.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photoresist composition, comprising:
a first polymer comprising:
a first repeating unit comprising a hydroxyaryl group;
a second repeating unit comprising a first acid-labile group; and
a third repeating unit comprising a first base-soluble group, wherein the first base-soluble group has a pKa of 12 or less, and wherein the first base-soluble group does not comprise a hydroxyaryl group;
wherein the first repeating unit, the second repeating unit, and the third repeating unit of the first polymer are structurally different from each other, and wherein the first polymer is free of lactone groups;
a second polymer comprising:
a first repeating unit comprising a second acid-labile group,
a second repeating unit comprising a lactone group, and
a third repeating unit comprising a second base-soluble group having a pKa of 12 or less;
wherein the first repeating unit, the second repeating unit, and the third repeating unit of the second polymer are structurally different from each other; and
a solvent,
wherein the first polymer and the second polymer are different from each other.

2. The photoresist composition of claim 1, further comprising a photoacid generator.

3. The photoresist composition of claim 1, wherein the first base-soluble group comprises a fluoroalcohol group, a carboxylic acid group, a sulfonimide group, a sulfonamide group, or carboximide group.

4. The photoresist composition of claim 3, wherein the third repeating unit of the first polymer is derived from a monomer of formula (3): 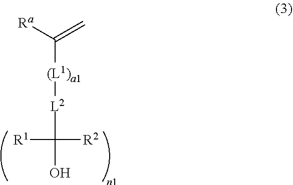
wherein, in formula (3),
R^{a} is hydrogen, halogen, or substituted or unsubstituted C₁₋₁₀ alkyl;
L¹ is —O—, —C(O)—, or —C(O)O—, or —C(O)NR′— wherein R′ is hydrogen or a substituted or unsubstituted C₁₋₅ alkyl group;
a1 is 0 or 1;
L² is a single bond or a multivalent linking group;
each R¹ is a substituted or unsubstituted C₁₋₁₂ perfluoroalkyl group;
each R² is substituted or unsubstituted C₁₋₁₂ alkyl, substituted or unsubstituted C₃₋₁₂ cycloalkyl, or substituted or unsubstituted C₁₋₁₂ heterocycloalkyl, wherein R² optionally comprises one or more fluorine atoms; and
n1 is an integer from 1 to 5.

5. The photoresist composition of claim 1, wherein the first repeating unit of the first polymer is derived from a monomer of formula (1): 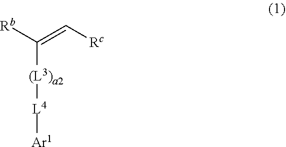
wherein, in Formula (1),
R^{b} is hydrogen, halogen, or substituted or unsubstituted C₁₋₁₀ alkyl;
R^{c} is hydrogen, —C(O)— forming a ring with L⁴, or a single bond forming a ring with Ar¹;
L³ is —O—, —C(O)—, or —C(O)O—, wherein a2 is 0 or 1;
L⁴ is a single bond, or one or more divalent linking groups; and
Ar¹ comprises a hydroxy-substituted C₆₋₆₀ aryl group, a hydroxy-substituted C₅₋₆₀ heteroaryl group, or a combination thereof, each optionally further substituted with one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, or substituted or unsubstituted C₄₋₃₀ heteroarylalkyl, —OR^{1c}, or —NR^{1d}R^{1e}, wherein R^{1c} to R^{1e} are each independently substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₃₋₃₀ heteroaryl, or substituted or unsubstituted C₄₋₃₀ heteroarylalkyl.

6. The photoresist composition of claim 1, wherein the first acid-labile group and the second acid-labile group are each independently chosen from tertiary ester groups.

7. The photoresist composition of claim 1, wherein the second repeating unit of the second polymer is derived from a monomer of Formulae (4a) or (4b): 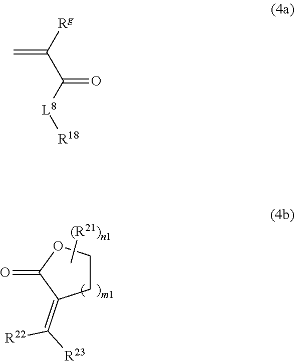
wherein, in Formulae (4a) and (4b),
R^{g} is hydrogen, halogen, or substituted or unsubstituted C₁₋₁₀ alkyl;
L⁸ is a single bond, or one or more divalent linking groups;
R¹⁸ is a substituted or unsubstituted C₄₋₂₀ lactone-containing group;
each R²¹ is independently halogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl, wherein each R¹ optionally further comprises a divalent linking group as part of its structure;
R²² and R²³ are each independently hydrogen, halogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₃₋₂₀ heterocycloalkyl, C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl, wherein each of R²² and R²³ independently optionally further comprises a divalent linking group as part of their structure;
m1 is 1 or 2; and
n1 is an integer from 1 to 6.

8. The photoresist composition of claim 1, wherein the third repeating unit of the second polymer is derived from a monomer of Formulae (5a), (5b), (5c), or (5d): 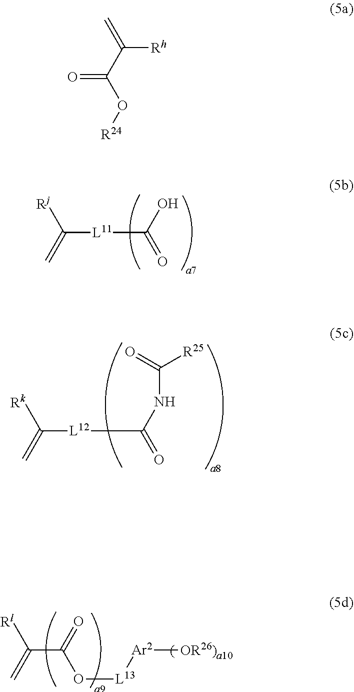
wherein, in Formulae (5a), (5b), (5c), and (5d),
R^{h}, R^{j}, R^{k}, and R^{l} are each independently hydrogen, halogen, or substituted or unsubstituted C₁₋₁₀ alkyl;
L¹¹, L¹², and L¹³ are each independently a single bond or a multivalent linking group;
Ar² is substituted or unsubstituted C₆₋₃₀ aryl, or substituted or unsubstituted C₃₋₃₀ heteroaryl;
R²⁴ and R²⁵ are each independently substituted or unsubstituted C₁₋₂₀ alkyl;
R²⁵ is hydrogen or methyl;
a7 and a8 are each independently an integer from 1 to 5;
a9 is 0 or 1; and
a10 is an integer from 1 to 12.

9. The photoresist composition of claim 1, wherein a weight ratio of the first polymer to the second polymer is from 1:4 to 4:1.

10. A method for forming a pattern, the method comprising:
(a) forming a photoresist layer from a photoresist composition of claim 1 on a substrate;
(b) pattern-wise exposing the photoresist layer to activating radiation; and
(c) developing the exposed photoresist layer to provide a resist relief image.

11. The method of claim 10, wherein the photoresist composition further comprises a photoacid generator.

12. The method of claim 10, wherein the first base-soluble group comprises a fluoroalcohol group, a carboxylic acid group, a sulfonimide group, a sulfonamide group, or carboximide group.

13. The method of claim 10, wherein the third repeating unit of the first polymer is derived from a monomer of formula (3): 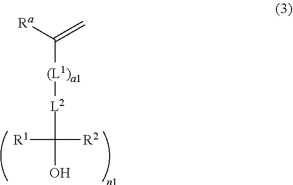
wherein, in formula (3),
R^{a} is hydrogen, halogen, or substituted or unsubstituted C₁₋₁₀ alkyl;
L¹ is —O—, —C(O)—, or —C(O)O—, or —C(O)NR′— wherein R′ is hydrogen or a substituted or unsubstituted C₁₋₅ alkyl group;
a1 is 0 or 1;
L² is a single bond or a multivalent linking group;
each R¹ is a substituted or unsubstituted C₁₋₁₂ perfluoroalkyl group;
each R² is substituted or unsubstituted C₁₋₁₂ alkyl, substituted or unsubstituted C₃₋₁₂ cycloalkyl, or substituted or unsubstituted C₁₋₁₂ heterocycloalkyl, wherein R² optionally comprises one or more fluorine atoms; and
n1 is an integer from 1 to 5.

14. The method of claim 10, wherein the first repeating unit of the first polymer is derived from a monomer of formula (1): 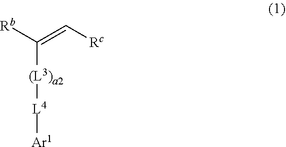
wherein, in Formula (1),
R^{b} is hydrogen, halogen, or substituted or unsubstituted C₁₋₁₀ alkyl;
R^{c} is hydrogen, —C(O)— forming a ring with L⁴, or a single bond forming a ring with Ar¹;
L³ is —O—, —C(O)—, or —C(O)O—, wherein a2 is 0 or 1;
L⁴ is a single bond, or one or more divalent linking groups; and
Ar¹ comprises a hydroxy-substituted C₆₋₆₀ aryl group, a hydroxy-substituted C₅₋₆₀ heteroaryl group, or a combination thereof, each optionally further substituted with one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, or substituted or unsubstituted C₄₋₃₀ heteroarylalkyl, —OR^{1c}, or —NR^{1d}R^{1e}, wherein R^{1c} to R^{1e} are each independently substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₃₋₃₀ heteroaryl, or substituted or unsubstituted C₄₋₃₀ heteroarylalkyl.

15. The method of claim 10, wherein the first acid-labile group and the second acid-labile group are each independently chosen from tertiary ester groups.

16. The method of claim 10, wherein the second repeating unit of the second polymer is derived from a monomer of Formulae (4a) or (4b): 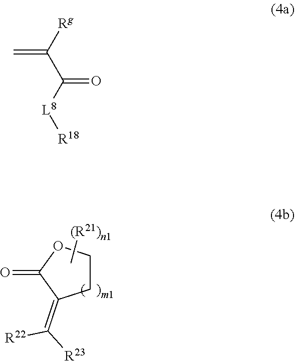
wherein, in Formulae (4a) and (4b),
R^{g} is hydrogen, halogen, or substituted or unsubstituted C₁₋₁₀ alkyl;
L⁸ is a single bond, or one or more divalent linking groups;
R¹⁸ is a substituted or unsubstituted C₄₋₂₀ lactone-containing group;
each R²¹ is independently halogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl, wherein each R¹ optionally further comprises a divalent linking group as part of its structure;
R²² and R²³ are each independently hydrogen, halogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₃₋₂₀ heterocycloalkyl, C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl, wherein each of R²² and R²³ independently optionally further comprises a divalent linking group as part of their structure;
m1 is 1 or 2; and
n1 is an integer from 1 to 6.

17. The method of claim 10, wherein the third repeating unit of the second polymer is derived from a monomer of Formulae (5a), (5b), (5c), or (5d): 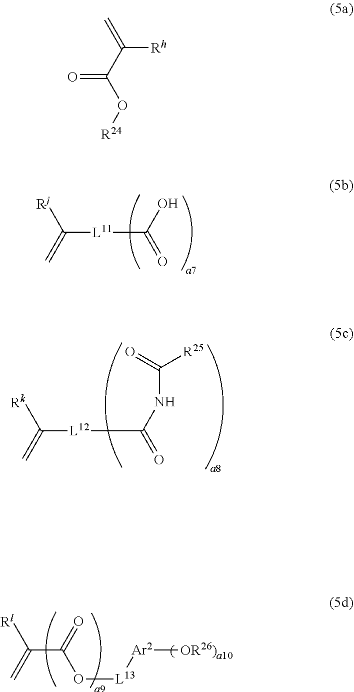
wherein, in Formulae (5a), (5b), (5c), and (5d),
R^{h}, R^{j}, R^{k}, and R^{l} are each independently hydrogen, halogen, or substituted or unsubstituted C₁₋₁₀ alkyl;
L¹¹, L¹², and L¹³ are each independently a single bond or a multivalent linking group;
Ar² is substituted or unsubstituted C₆₋₃₀ aryl, or substituted or unsubstituted C₃₋₃₀ heteroaryl;
R²⁴ and R²⁵ are each independently substituted or unsubstituted C₁₋₂₀ alkyl;
R²⁵ is hydrogen or methyl;
a7 and a8 are each independently an integer from 1 to 5;
a9 is 0 or 1; and
a10 is an integer from 1 to 12.

18. The method of claim 10, wherein a weight ratio of the first polymer to the second polymer is from 1:4 to 4:1.
